(19) United States
(12) Patent Application Publication
(10) Pub. No.: US 2024/0224610 A1
(43) Pub. Date: Jul. 4, 2024

(54) DISPLAY DEVICE

(71) Applicant: LG Display Co., Ltd., Seoul (KR)

(72) Inventors: Jonghan PARK, Seoul (KR); SeungHee NAM, Paju-si (KR); YunHo KOOK, Goyang-si (KR); Eun Young PARK, Paju-si (KR); Chaewoon LEE, Seoul (KR)

(21) Appl. No.: 18/502,749

(22) Filed: Nov. 6, 2023

(30) Foreign Application Priority Data
Dec. 30, 2022 (KR) 10-2022-0190944

(51) Int. Cl. H10K 59/122; H10K 59/80

(52) U.S. Cl. CPC H10K 59/122; H10K 59/878

(57) ABSTRACT

A display device includes a substrate including a plurality of sub pixels. The device includes a transistor disposed above the substrate. The device includes a planarization layer which is disposed above the transistor and has a first open area. The device includes an anode electrode which is disposed in the first open area and a side portion of the planarization layer adjacent to the first open area. The device includes a bank which covers a part of the anode electrode and has a second open area corresponding to the first open area. The device includes an organic layer which is disposed on the anode electrode exposed by the second open area. The device includes a cathode electrode disposed on the organic layer, and a side portion of the planarization layer has a bumpy shape and an end of the anode electrode has a bumpy shape from a plan view.

### CROSS-REFERENCE TO RELATED APPLICATIONS

This application claims the priority of Korean Patent Application No.10-2022-0190944 filed on Dec. 30, 2023, in the Korean Intellectual Property Office, the disclosure of which is incorporated herein by reference.

### BACKGROUND

### Technical Field

The present disclosure relates to a display device, and more particularly, to a display device which improves a light extraction efficiency and improves a rainbow mura.

### Description of the Related Art

As it enters the information era, a field of a display device which visually expresses electrical information signals has been rapidly developed and studies are continuing to improve performances of various display devices, such as a thin-thickness, a light weight, and low power consumption.

A representative display device may include a liquid crystal display (LCD) device, a field emission display (FED) device, an electro-wetting display (EWD) device, an organic light emitting display (OLED) device, and the like.

An electroluminescent display device which is represented by an organic light emitting display device is a self-emitting display device so that a separate light source is not necessary, which is different from a liquid crystal display device. Therefore, the electroluminescent display device may be manufactured to have a light weight and a small thickness. Further, since the electroluminescent display device is advantageous not only in terms of power consumption due to the low voltage driving, but also in terms of color implementation, a response speed, a viewing angle, a contrast ratio (CR), it is expected to be utilized in various fields.

The electroluminescent display device configures a light emitting diode by disposing a plurality of organic layers each including an emission layer between two electrodes of an anode electrode and a cathode electrode. For example, when holes are injected from the anode electrode into the emission layer and electrons are injected from the cathode electrode into the emission layer, the injected holes and electrons are recombined in the emission layer to form excitons and emit light.

### BRIEF SUMMARY

However, the inventors have realized that the electroluminescent display device in the related art has a problem in that there is light which does not go out from a display panel and is trapped in the display panel. Because some part of the light emitted from an emission layer is trapped in the display panel, a light extraction efficiency is degraded and luminous efficiency is also degraded.

Therefore, various embodiments of the present disclosure provide a display device which improves a light extraction efficiency and improves a luminance viewing angle.

Various embodiments of the present disclosure provide a display device which improves a rainbow mura.

Various embodiments of the present disclosure provide a display device which improves a rainbow mura of a plurality of sub pixels which is disposed in different forms.

The technical benefits of the present disclosure are not limited to the above-mentioned benefits, and other benefits, which are not mentioned above, can be clearly understood by those skilled in the art from the following descriptions.

In order to achieve the above-described benefits, according to an aspect of the present disclosure, a display device includes a substrate including a plurality of sub pixels; a transistor disposed above the substrate; a planarization layer which is disposed above the transistor and has a first open area; an anode electrode which is disposed in the first open area and a side portion of the planarization layer opposite to the first open area; a bank which covers a part of the anode electrode and has a second open area corresponding to the first open area; an organic layer which is disposed on the anode electrode exposed by the second open area; and a cathode electrode disposed on the organic layer, and a side portion of the planarization layer has a bumpy shape as seen from the plane and an end of the anode electrode has a bumpy shape as seen from the plane.

Other detailed matters of the exemplary embodiments are included in the detailed description and the drawings.

According to the present disclosure, an anode electrode includes a side mirror structure so that a display device with an excellent luminous efficiency may be provided.

According to the present disclosure, a side portion of a planarization layer and an edge of an open area are patterned to increase an area of the side mirror to improve the luminous efficiency and improve the luminance viewing angle.

According to the present disclosure, a periodicity of the side portion of the planarization layer and the edge pattern of the open area is reduced to improve a concentric rainbow mura through irregular reflection.

According to the present disclosure, an area of the anode electrode is reduced or minimized and a shape of the anode is designed to be different for every sub pixel to further improve the rainbow mura.

The effects according to the present disclosure are not limited to the contents exemplified above, and more various effects are included in the present specification.

### BRIEF DESCRIPTION OF THE SEVERAL VIEWS OF THE DRAWINGS

The above and other aspects, features and other advantages of the present disclosure will be more clearly understood from the following detailed description taken in conjunction with the accompanying drawings, in which:

FIG. 1 is a diagram exemplarily illustrating a display device according to the present disclosure;

FIG. 2 is a plan view schematically illustrating a display device according to the present disclosure;

FIG. 3 is an equivalent circuit of a sub pixel of a display device according to the present disclosure;

FIG. 4 is a view illustrating a sub pixel structure of a first exemplary embodiment of the present disclosure;

FIG. 5 is a view illustrating a cross-sectional structure of a display panel according to a first exemplary embodiment of the present disclosure;

FIG. 6A is a perspective view exemplarily illustrating a first open area of a third planarization layer in a sub pixel structure of FIG. 5;

FIG. 6B is a perspective view exemplarily illustrating a second open area of a bank in a sub pixel structure of FIG. 5;

FIGS. 7A and 7B are views illustrating an emission image of a comparative embodiment;

FIG. 8 is a view exemplarily illustrating an emission image according to a first exemplary embodiment of the present disclosure;

FIG. 9 is a view illustrating a sub pixel structure of a second exemplary embodiment of the present disclosure;

FIG. 10 is a view exemplarily illustrating an emission image according to a second exemplary embodiment of the present disclosure;

FIGS. 11A to 11C are views illustrating a mura image;

FIG. 12 is a view illustrating a sub pixel structure of a third exemplary embodiment of the present disclosure;

FIG. 13 is a view illustrating a sub pixel structure of a fourth exemplary embodiment of the present disclosure;

FIG. 14 is a view illustrating a cross-sectional structure of a display panel according to a fourth exemplary embodiment of the present disclosure; and

FIG. 15 is a view illustrating a sub pixel structure of a fifth exemplary embodiment of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, dimensions (e.g., length, width, height, thickness, radius, diameter, area, etc.), ratios, angles, number of elements, and the like illustrated in the accompanying drawings for describing the exemplary embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Like reference numerals generally denote like elements throughout the specification. Further, in the following description of the present disclosure, a detailed explanation of known related technologies may be omitted to avoid unnecessarily obscuring the subject matter of the present disclosure. The terms such as ‘including,’ ‘having,’ ‘consist of’ used herein are generally intended to allow other components to be added unless the terms are used with the term ‘only.’ Any references to singular may include plural unless expressly stated otherwise.

Components are interpreted to include an ordinary error range even if not expressly stated.

When the position relation between two parts is described using the terms such as ‘on,’ ‘above,’ ‘below,’ ‘next,’ one or more parts may be positioned between the two parts unless the terms are used with the term ‘immediately’ or ‘directly.’

When an element or layer is disposed “on” another element or layer, another layer or another element may be interposed directly on the other element or therebetween.

Although the terms “first,” “second,” and the like are used for describing various components, these components are not confined by these terms. These terms are merely used for distinguishing one component from the other components. Therefore, a first component to be mentioned below may be a second component in a technical concept of the present disclosure.

The features of various embodiments of the present disclosure can be partially or entirely adhered to or combined with each other and can be interlocked and operated in technically various ways, and the embodiments can be carried out independently of or in association with each other.

Hereinafter, various embodiments of the present disclosure will be described in detail with reference to accompanying drawings.

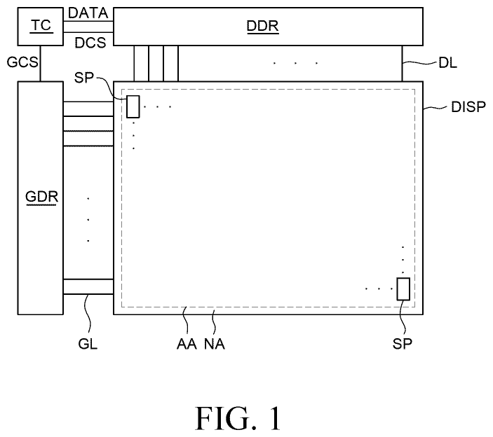

FIG. 1 is a diagram exemplarily illustrating a display device according to the present disclosure.

A display device according to exemplary embodiments of the present disclosure may include a display device, an illumination device, an electroluminescent display device, and the like. Hereinafter, for the convenience of description, the display device will be mainly described. However, the following description will be applied to other various display devices, such as an illumination device or an electroluminescent display device, in the same way.

Referring to FIG. 1, the display device according to the exemplary embodiments of the present disclosure may include a display panel DISP which displays an image or outputs light and a driving circuit which drives the display panel DISP.

In the display panel DISP, a plurality of data lines DL and a plurality of gate lines GL are disposed and a plurality of sub pixels SP defined by the plurality of data lines DL and the plurality of gate lines GL may be disposed in a matrix.

The plurality of data lines DL and the plurality of gate lines GL of the display panel DISP may intersect each other. For example, the plurality of gate lines GL may be disposed in the unit of rows or columns and the plurality of data lines DL may be disposed in the unit of columns or rows. Hereinafter, for the convenience of description, it is assumed that the plurality of gate lines GL is disposed in rows and the plurality of data lines DL is disposed in columns.

In the display panel DISP, according to a sub pixel structure, another types of signal lines may be disposed, other than the plurality of data lines DL and the plurality of gate lines GL. For example, a driving voltage line, a reference voltage line, a common voltage line, or the like may be further disposed.

The display panel DISP may be various types of panels, such as a liquid crystal display (LCD) panel or an organic light emitting diode (OLED) panel.

A type of signal lines disposed in the display panel DISP may vary depending on a sub pixel structure or a panel type. Further, in the present disclosure, a signal line may be a concept including an electrode to which a signal is applied.

The display panel DISP may include an active area AA in which images are displayed and a non-active area NA which is an outer periphery of the active area AA and does not display images. Here, the non-active area NA is also referred to as a bezel area.

In the active area AA, a plurality of sub pixels SP may be disposed to display images.

In the non-active area NA, a pad unit to which a data driver DDR is electrically connected is disposed and a plurality of data link lines may be disposed to connect the pad unit and the plurality of data lines DL. Here, the plurality of data link lines may be parts formed by extending the plurality of data lines DL to the non-active area NA or separate patterns which are electrically connected to the plurality of data lines DL.

Further, in the non-active area NA, gate driving-related lines for transmitting a voltage required to drive the gate to the gate driver GDR through the pad unit to which the above-described data driver DDR is electrically connected. For example, the gate driving-related lines may include a clock line which transmits a clock signal, a gate voltage line which transmits gate voltages VGH and VGL, and a gate driving control signal line which transmits various control signals required to generate a scan signal. Such gate driving-related lines may be disposed in the non-active area NA, unlike the gate line GL which is disposed in the active area AA.

For example, the driving circuit may include a data driver DDR which drives the plurality of data lines DL, a gate driver GDR which drives the plurality of gate lines GL, and a timing controller TC which controls the data driver DDR and the gate driver GDR.

As described above, the data driver DDR outputs a data voltage to the plurality of data lines DL to drive the plurality of data lines DL.

Further, the gate driver GDR outputs the scan signal to the plurality of gate lines GL to drive the plurality of gate lines GL.

For example, the timing controller TC supplies various control signals DCS and GCS required for the driving operations of the data driver DDR and the gate driver GDR to control the driving operations of the data driver DDR and the gate driver GDR. Further, the timing controller TC may supply image data DATA to the data driver DDR.

The timing controller TC may start scanning according to a timing implemented in each frame, convert input image data input from the outside to be suitable for a data signal form used by the data driver DDR to output the converted image data DATA, and control data driving at a proper time in accordance with the scanning.

For example, the timing controller TC receives timing signals, such as a vertical synchronization signal Vsync, a horizontal synchronization signal Hsync, an input data enable (DE) signal, and a clock signal CLK, from the outside to control the data driver DDR and the gate driver GDR to generate various control signals. Therefore, the timing controller may output the generated various control signals to the data driver DDR and the gate driver GDR.

For example, in order to control the gate driver GDR, the timing controller TC may output various gate control signals GCS including a gate start pulse GSP, a gate shift clock GSC, and a gate output enable signal GOE.

Further, in order to control the data driver DDR, the timing controller TC may output various data control signals DCS including a source start pulse SSP, a source sampling clock SSC. and a source output enable signal SOE.

The timing controller TC may be implemented as a component separated from the data driver DDR or may be integrated with the data driver DDR to be implemented as an integrated circuit.

The data driver DDR receives image data DATA from the timing controller TC to supply a data voltage to the plurality of data lines DL to drive the plurality of data lines DL. The data driver DDR is also referred to as a source driver.

The data driver DDR may exchange various signals with the timing controller TC through various interfaces.

Further, the gate driver GDR sequentially supplies the scan signal to the plurality of gate lines GL to sequentially drive the plurality of gate lines GL. Here, the gate driver GDR is also referred to as a scan driver.

The gate driver GDR may sequentially supply a scan signal of an on-voltage or an off-voltage to the plurality of gate lines GL in accordance with the control of the timing controller TC.

When a specific gate line is open by the gate driver GDR, the data driver DDR converts image data DATA received from the timing controller TC into an analog data voltage to supply the converted analog data voltage to the plurality of data lines DL.

The data driver DDR may be disposed only on one side of the display panel DISP or if necessary, may be disposed on both sides of the display panel DISP according to a driving method and a panel design method. For example, the data driver DDR may be disposed on or below the display panel DISP or disposed on and below the display panel DISP.

The gate driver GDR may be disposed only on one side of the display panel DISP or if necessary, may be disposed on both sides of the display panel DISP according to a driving method and a panel design method. For example, the gate driver GDR may be disposed on a left side or a right side of the display panel DISP or disposed on both the left side and the right side of the display panel DISP.

The data driver DDR may be implemented to include one or more source driver integrated circuits (SDIC).

For example, each source driver integrated circuit may include a shift register, a latch circuit, a digital to analog converter (DAC), an output buffer, or the like. The data driver DDR may further include one or more analog to digital converters (ADC), if necessary.

Further, each source driver integrated circuit may be connected to a bonding pad of the display panel DISP as a tape automated bonding type (TAB) or a chip on glass (COG) type or may be disposed directly on the display panel DISP. If necessary, each source driver integrated circuit may be integrated in the display panel DISP to be disposed. Further, each source driver integrated circuit may be implemented as a chip on film (COF) type. In this case, each source driver integrated circuit is mounted on a circuit film to be electrically connected to the data line DL in the display panel DISP through the circuit film.

The gate driver GDR may be configured by a plurality of gate driving circuits. Here, the plurality of gate driving circuits may correspond to the plurality of gate lines GL, respectively.

For example, each gate driving circuit may include a shift register, a level shifter, and the like.

The gate driving circuit may be connected to the bonding pad of the display panel DISP as a tape automated bonding (TAB) type or a chip on glass (COG) type. Further, each gate driving circuit may be implemented as a chip on film (COF) type. In this case, each gate driving circuit is mounted on a circuit film to be electrically connected to the gate line GL in the display panel DISP through the circuit film. Further, each gate driving circuit is implemented as a gate in panel (GIP) to be embedded in the display panel DISP. For example, each gate driving circuit may be directly formed in the display panel DISP.

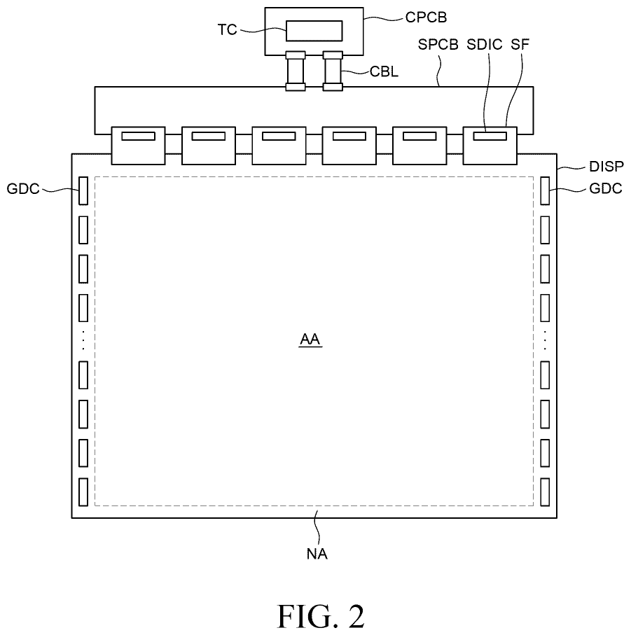

FIG. 2 is a plan view schematically illustrating a display device according to the present disclosure.

Referring to FIG. 2, in the display device according to exemplary embodiments of the present disclosure, the data driver may be implemented as a chip on film (COF) type, among the above-described various types TAB, COG, and COF and the gate driver may be implemented as a gate in panel (GIP) type, among various types TAB, COG, COF, and GIP. However, it is not limited thereto and may be implemented as various types.

The data driver may be implemented by one or more source driver integrated circuits (SDIC). FIG. 2 illustrates that the data driver is implemented as a plurality of source driver integrated circuits (SDIC), but is not limited thereto.

When the data driver is implemented as a COF type, each source driver integrated circuit (SDIC) which implements a data driver may be mounted on the source-side circuit film SF.

For example, one side of the source-side circuit film SF may be electrically connected to a pad unit (an assembly of pads) disposed in the non-active area NA of the display panel DISP.

Further, wiring lines which electrically connect the source driver integrated circuit SDIC and the display panel DISP may be disposed on the source-side circuit film SF.

The display device may include one or more source printed circuit boards SPCB and a control printed circuit board CPCB for mounting control components and various electric devices, for circuit connections between the plurality of source driver integrated circuit SDIC and the other devices.

For example, the other side of the source-side circuit film SF in which the source driver integrated circuit SDIC is mounted may be connected to one or more source printed circuit boards SPCB. For example, one side of the source-side circuit film SF in which the source driver integrated circuit SDIC is mounted may be electrically connected to the non-active area NA of the display panel DISP and the other side may be electrically connected to the source printed circuit board SPCB.

Further, in the control printed circuit board CPCB, a timing controller TC which controls the operations of the data driver and the gate driver GDR may be disposed.

In the control printed circuit board CPCB, a power management IC (PMIC) which supplies various voltages or currents to the display panel DISP, the data driver, and the gate driver or controls various voltages or currents to be supplied may be further disposed.

The source printed circuit board SPCB and the control printed circuit board CPCB may be circuitically connected through at least one connection member CBL.

For example, the connection member CBL may be a flexible printed circuit FPC, a flexible flat cable FFC, or the like.

For example, one or more source printed circuit boards SPCB and the control printed circuit board CPCB may be integrated as one printed circuit board to be implemented.

When the gate driver is implemented as a gate in panel (GIP) type, the plurality of gate driving circuits GDC included in the gate driver may be directly formed on the non-active area NA of the display panel DISP.

Each gate driving circuit GDC may output the scan signal to a corresponding gate line disposed in the active area AA in the display panel DISP.

The plurality of gate driving circuits GDC disposed on the display panel DISP may be supplied with various signals (a clock signal, a high level gate voltage VGH, a low level gate voltage VGL, a start signal VST, a reset signal RST, and the like) required to generate the scan signal through gate driving-related lines disposed in the non-active area NA.

The gate driving-related lines disposed in the non-active area NA may be electrically connected to the source-side circuit film SF which is most adjacent to the plurality of gate driving circuits GDC.

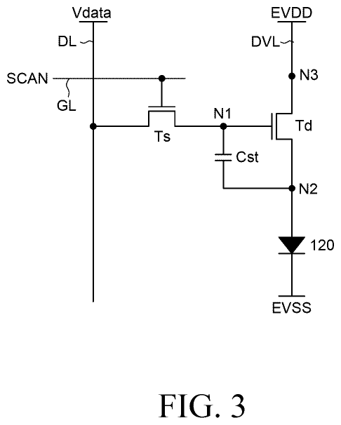

FIG. 3 is an equivalent circuit of a sub pixel of a display device according to the present disclosure.

FIG. 3 is an equivalent circuit of one sub pixel when a display panel according to exemplary embodiments of the present disclosure is an electroluminescent display panel.

Referring to FIG. 3, each sub pixel includes a light emitting diode 120, a driving transistor Td which drives the light emitting diode 120, a switching transistor Ts which is electrically connected between a first node N1 of the driving transistor Td and the corresponding data line DL, and a storage capacitor Cst to be implemented. The storage capacitor Cst is electrically connected between the first node N1 and a second node N2 of the driving transistor Td.

The light emitting diode 120 may be configured by an anode electrode, a plurality of organic layers, a cathode electrode, and the like.

Referring to FIG. 3, the anode electrode (also referred to as a pixel electrode) of the light emitting diode 120 may be electrically connected to the second node N2 of the driving transistor Td. In this case, a base voltage EVSS may be applied to the cathode electrode (also referred to as a common electrode) of the light emitting diode 120.

The base voltage EVSS may be a ground voltage or a voltage higher than or lower than the ground voltage. Further, the base voltage EVSS may vary depending on a driving state. For example, a base voltage EVSS during the image driving and a base voltage EVSS during sensing driving may be set to be different.

The driving transistor Td supplies a driving current to the light emitting diode 120 to drive the light emitting diode 120.

The driving transistor Td may include a first node N1, a second node N2, and a third node N3.

The first node N1 of the driving transistor Td may be a gate node and may be electrically connected to a source node or a drain node of the switching transistor Ts. The second node N2 of the driving transistor Td may be a source node or a drain node and may be electrically connected to an anode electrode (or a cathode electrode) of the light emitting diode 120. The third node N3 of the driving transistor Td may be a drain node or a source node, may be applied with a driving voltage EVDD, and may be electrically connected to a driving voltage line DVL which supplies the driving voltage EVDD.

The storage capacitor Cst is electrically connected between the first node N1 and the second node N2 of the driving transistor Td to maintain a data voltage Vdata corresponding to an image signal voltage or a voltage corresponding thereto for one frame time (or a selected time).

The drain node or the source node of the switching transistor Ts may be electrically connected to a corresponding data line DL and the source node or the drain node of the switching transistor Ts may be electrically connected to the first node N1 of the driving transistor Td. Further, the gate node of the switching transistor Ts is electrically connected to the gate line to be applied with a scan signal SCAN.

The switching transistor Ts is applied with the scan signal SCAN through the gate node by means of the gate line to be controlled to be turned on or off.

The switching transistor Ts is turned on by the scan signal SCAN to transmit a data voltage Vdata supplied from the data line DL to the first node N1 of the driving transistor Td.

In the meantime, the storage capacitor Cst may be an external capacitor which is intentionally designed at the outside of the driving transistor Td, rather than a parasitic capacitor which is an internal capacitor present between the first node N1 and the second node N2 of the driving transistor Td.

For example, each of the driving transistor Td and the switching transistor Ts may be an n-type transistor or a p-type transistor.

Each sub pixel structure illustrated in FIG. 3 is a 2T (transistor) 1C (capacitor) structure, but this is just illustrative, so that the sub pixel structure may further include one or more transistors or if necessary, further include one or more capacitors. Alternatively, the plurality of sub pixels may have the same structure or some of the plurality of sub pixels may have a different structure.

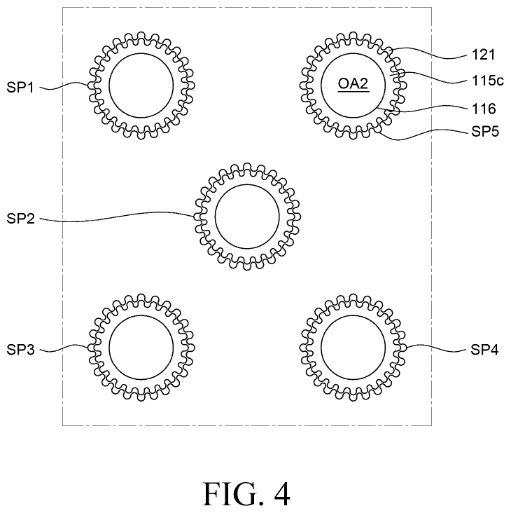

FIG. 4 is a view illustrating a sub pixel structure of a first exemplary embodiment of the present disclosure.

FIG. 4 illustrates a part of a display panel in which five sub pixels SP1, SP2, SP3, SP4, and SP5 are disposed as an example and exemplarily illustrates a bank 116 including a second open area OA2 which is an emission area, an anode electrode 121, and a third planarization layer 115c (see SP5, for example). For brevity purposes, in the following description, only 3 sub pixels SP1, SP2, and SP3 will be described.

Referring to FIG. 4, the display panel according to the first exemplary embodiment of the present disclosure may include a pixel area in which a plurality of sub pixels SP1, SP2, and SP3 is provided and a wiring area in which various signal lines are disposed.

A plurality of first sub pixels SP1, second sub pixels SP2, and third sub pixels SP3 may be disposed in the pixel area.

For example, the first sub pixel SP1 may be a red sub pixel.

For example, the second sub pixel SP2 may be a green sub pixel.

For example, the third sub pixel SP3 may be a blue sub pixel.

For example, the first sub pixel SP1, the second sub pixel SP2, and the third sub pixel SP3 may have a circular shape or a polygonal shape, but are not limited thereto. Here, a shape of the sub pixels SP1, SP2, and SP3 is defined by the shape of the anode electrode 121, but the present disclosure is not limited thereto.

In FIG. 4, it is illustrated that one first sub pixel SP1, one second sub pixel SP2, and one third sub pixel SP3 are gathered to configure one pixel, but is not limited thereto.

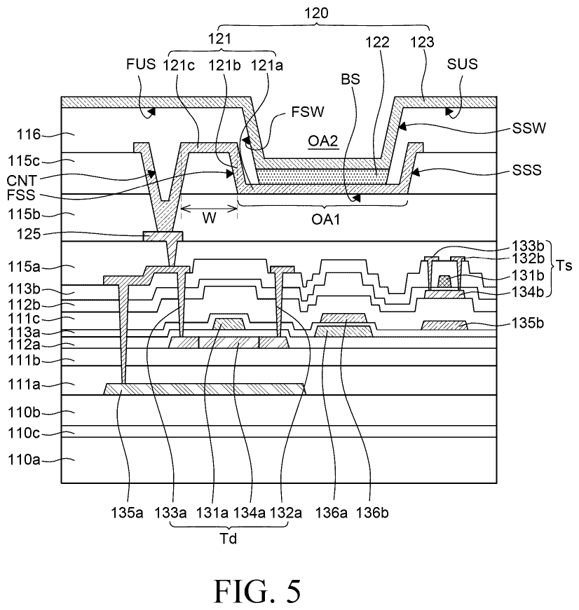

In the meantime, according to the present disclosure, due to the side mirror SM structure of the anode electrode 121, a reflective emission area is added as well as a main emission area so that the emission area may be expanded as compared with each of the sub pixels SP1, SP2, and SP3. Detailed description regarding the side mirror structure will be made below with reference to FIGS. 5 to 7.

According to a first exemplary embodiment of the present disclosure, a side portion of the third planarization layer 115c which is abut with a side surface of the anode electrode 121 having a side mirror structure has a bumpy shape, such as an iris or wavy pattern as seen from a plan view. Therefore, an area of the side mirror of the anode electrode 121 may be substantially increased. By doing this, a luminous efficiency may be improved, a luminance viewing angle may be improved, and a concentric rainbow mura may be improved by the irregular reflection.

In the meantime, according to the first exemplary embodiment of the present disclosure, one end of the anode electrode 121 may have a bumpy shape as seen from the plane. A shape of the anode electrode 121 will be described in more detail below with reference to FIGS. 5 to 8 together.

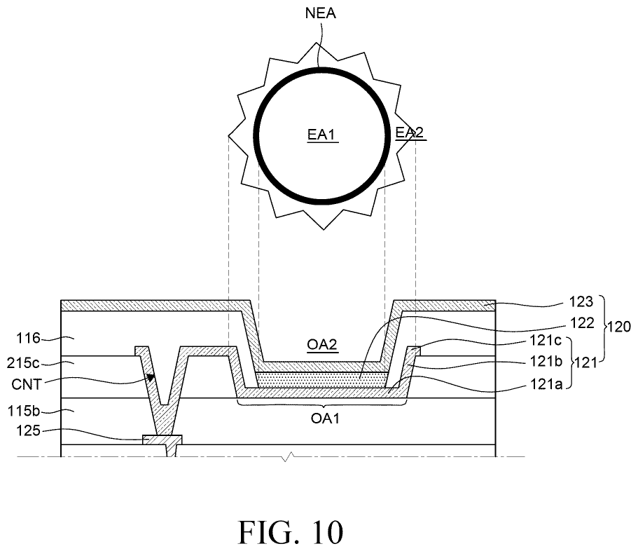

The term “bumpy” as used herein is used to include the meaning of protrusions as well as ridges and valleys formed by the protrusions at a periphery surface of the planarization layer as shown in FIGS. 4 and 9. For example, as shown in FIG. 4, in the second subpixel SP2, the ridges R1 and valleys V1 are alternately arranged to form a wavy pattern from a plan view.

FIG. 5 is a view illustrating a cross-sectional structure of a display panel according to a first exemplary embodiment of the present disclosure.

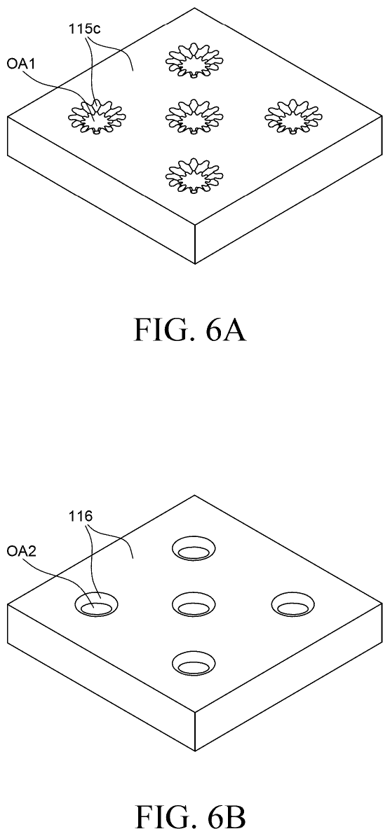

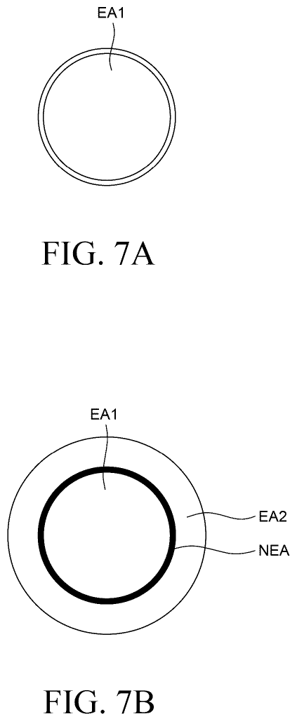

FIG. 6A is a perspective view exemplarily illustrating a first open area of a third planarization layer in a sub pixel structure of FIG. 5.

FIG. 6B is a perspective view exemplarily illustrating a second open area of a bank in a sub pixel structure of FIG. 5.

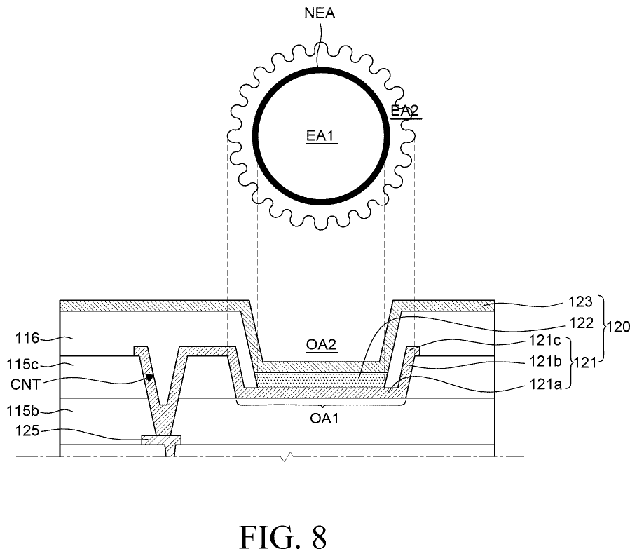

FIGS. 7A and 7B are views illustrating an emission image of a comparative embodiment.

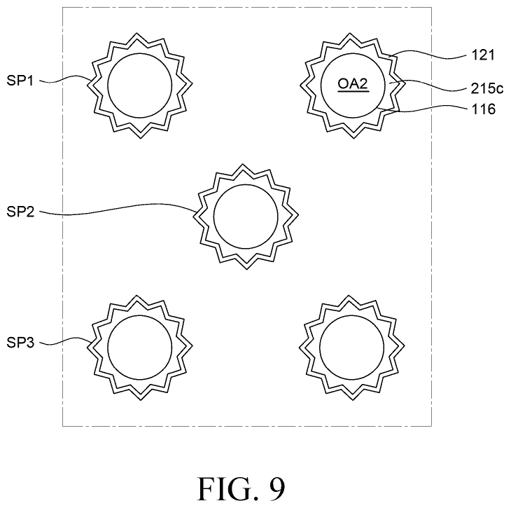

FIG. 8 is a view exemplarily illustrating an emission image according to a first exemplary embodiment of the present disclosure.

FIG. 5 illustrates a part of a cross section of one sub pixel of a display panel according to the first exemplary embodiment of the present disclosure.

Even though in FIG. 5, components above the light emitting diodes 120 are not illustrated for the convenience of description, the present disclosure is not limited thereto and the present disclosure may include an encapsulation layer, a touch sensor layer, and the like above the light emitting diode 120.

FIGS. 6A and 6B illustrate, as an example, a first open area OA1 of a third planarization layer 115c and a second open area OA2 of the bank 116 included in the display panel according to the first exemplary embodiment of the present disclosure.

FIG. 7A illustrates an emission image of a comparative embodiment that the SM structure of the present disclosure is not applied as an example and FIG. 7B illustrates an emission area of a comparative embodiment that the SM structure is applied, but a side portion of the third planarization layer has a circular shape, as an example.

FIG. 8 exemplarily illustrates a part of a cross-sectional structure of a sub pixel illustrated in FIG. 5 and an emission image corresponding thereto.

Referring to FIGS. 5, 6A, 6B, and 8, a driving transistor Td, a switching transistor Ts, and a light emitting diode 120 may be disposed above substrates 110a, 110b, and 110c.

For example, the substrates 110a, 110b, and 110c may include a first substrate 110a, a second substrate 110b, and an interlayer insulating layer 110c. The interlayer insulating layer 110c may be disposed between the first substrate 110a and the second substrate 110b.

As described above, the substrates 110a, 110b, and 110c include a first substrate 110a, a second substrate 110b, and an interlayer insulating layer 110c to suppress permeation of the moisture. For example, the first substrate 110a and the second substrate 110b may be polyimide (PI) substrates.

Transistors, such as a driving transistor Td or a switching transistor Ts may be disposed above the substrates 110a, 110b, and 110c.

A multi-buffer layer 111a may be disposed on the second substrate 110b and an active buffer layer 111b may be disposed on the multi-buffer layer 111a.

A first light shielding layer 135a may be disposed above the second substrate 110b. However, it is not limited thereto and the first light shielding layer 135a may be disposed on the multi-buffer layer 111a.

The first light shielding layer 135a may serve to shield light.

The multi-buffer layer 111a may be disposed on the first light shielding layer 135a.

The active buffer layer 111b may be disposed on the multi-buffer layer 111a.

A first active layer 134a of the driving transistor Td may be disposed above the active buffer layer 111b.

A first gate insulating layer 112a may be disposed on the first active layer 134a.

Further, a first gate electrode 131a of the driving transistor Td may be disposed on the first gate insulating layer 112a.

Further, for example, a gate material layer 136a may be disposed on the first gate insulating layer 112a in a position different from a forming position of the driving transistor Td. For example, the gate material layer 136a may be a first storage electrode, but is not limited thereto.

The first interlayer insulating layer 113a may be disposed on the first gate electrode 131a.

A metal layer 136b may be disposed on the first interlayer insulating layer 113a. For example, the metal layer 136b may be a second storage electrode, but is not limited thereto.

In this case, the metal layer 136b may configure the storage capacitor together with the gate material layer 136a, but is not limited thereto.

Further, for example, a second light shielding layer 135b may be disposed on the first interlayer insulating layer 113a in a position different from a forming position of the metal layer 136b.

The buffer layer 111c may be disposed on the metal layer 136b and the second light shielding layer 135b.

A second active layer 134b of the switching transistor Ts may be disposed on the buffer layer 111c.

A second gate insulating layer 112b may be disposed on the second active layer 134b.

Further, a second gate electrode 131b of the switching transistor Ts may be disposed on the second gate insulating layer 112b.

The second interlayer insulating layer 113b may be disposed on the second gate electrode 131b.

A first source electrode 132a and a first drain electrode 133a of the driving transistor Td may be disposed on the second interlayer insulating layer 113b. Further, a second source electrode 132b and a second drain electrode 133b of the switching transistor Ts may be disposed on the second interlayer insulating layer 113b.

For example, the first source electrode 132a and the first drain electrode 133a may be electrically connected to one side and the other side of the first active layer 134a, respectively, through contact holes provided in the second interlayer insulating layer 113b, the second gate insulating layer 112b, the buffer layer 111c, the first interlayer insulating layer 113a, and the first gate insulating layer 112a.

For example, a part of the first drain electrode 133a may be electrically connected to one side of the first light shielding layer 135a through contact holes provided in the second interlayer insulating layer 113b, the second gate insulating layer 112b, the buffer layer 111c, the first interlayer insulating layer 113a, the first gate insulating layer 112a, the active buffer layer 111b, and the multi-buffer layer 111a.

Further, for example, the second source electrode 132b and the second drain electrode 133b may be electrically connected to one side and the other side of the second active layer 134b, through contact holes provided in the second interlayer insulating layer 113b and the second gate insulating layer 112b, respectively.

A part of the first active layer 134a which overlaps the first gate electrode 131a is a channel region. For example, one of the first source electrode 132a and the first drain electrode 133a may be connected to one side of the channel region in the first active layer 134a and the other one may be connected to the other side of the channel region in the first active layer 134a.

Further, a part of the second active layer 134b which overlaps the second gate electrode 131b is a channel region. For example, one of the second source electrode 132b and the second drain electrode 133b may be connected to one side of the channel region in the second active layer 134b and the other one may be connected to the other side of the channel region in the second active layer 134b.

Even though it is not illustrated, a passivation film may be disposed on the first source electrode 132a, the first drain electrode 133a, the second source electrode 132b, and the second drain electrode 133b.

The planarization layers 115a and 115b may be disposed above the first source electrode 132a, the first drain electrode 133a, the second source electrode 132b, and the second drain electrode 133b. For example, the planarization layers 115a and 115b may include a first planarization layer 115a and a second planarization layer 115b.

The first planarization layer 115a may be disposed on the passivation film.

The connection electrode 125 may be disposed on the first planarization layer 115a.

For example, the connection electrode 125 may be connected to one of the first source electrode 132a and the first drain electrode 133a through a contact hole provided in the first planarization layer 115a.

The second planarization layer 115b may be disposed on the connection electrode 125.

A third planarization layer 115c may be disposed on the second planarization layer 115b.

The third planarization layer 115c may be configured by an organic material, such as acrylic resin or epoxy resin, and for example, may be configured by photo acryl (PAC). The third planarization layer 115c may also be referred to as a planarization layer.

For example, the third planarization layer 115c may include a first open area OA1 obtained by removing (opening) a part corresponding to a main emission area EA1, a reflective emission area EA2, and a non-emission area NEA of the sub pixel.

As seen from the plane, the first open area OA1 may have an approximately (or entirely) circular shape with a bumpy edge such as an iris or wavy pattern (see FIG. 6A), but is not limited thereto.

The third planarization layer 115c may include a top surface and a side portion.

The top surface of the third planarization layer 115c is a surface located at the top of the third planarization layer 115c and may be substantially parallel to the second substrate 110b.

The side portion of the third planarization layer 115c is a surface extending from the top surface of the third planarization layer 115c to a side surface. For example, a side portion of the third planarization layer 115c may have a selected taper angle. For example, the side portion of the third planarization layer 115c may have a taper angle of 30° to 65°, but is not limited thereto.

As seen from the plane, the side portion of the third planarization layer 115c (or at the periphery surface of the third planarization layer 115c) may have a bumpy shape, such as an iris or wavy pattern (see FIG. 6A), like the edge of the first open area OA1, but is not limited thereto.

For example, the anode electrode 121 may be disposed on the top surface and the side portion of the third planarization layer 115c and the top surface of the second planarization layer 115b. For example, the anode electrode 121 may be disposed on the first open area OA1 and the top surface and the side portion of the third planarization layer 115c.

For example, the anode electrode 121 which is disposed in the first open area OA1 may be in contact with the top surface of the second planarization layer 115b.

For example, the anode electrode 121 may include a first area 121a which has a surface substantially parallel to a surface of the second substrate 110b in the first open area OA1 and a second area 121b which extends from the first area 121a so that a surface has a selected angle with respect to the second substrate 110b. Further, for example, the first area 121a of the anode electrode 121 may correspond to the first open area OA1. For example, the second area 121b of the anode electrode 121 may correspond to a side portion of the third planarization layer 115c. Therefore, the second area 121b of the anode electrode 121 may be referred to as a side portion of the anode electrode 121 (or a periphery surface of the anode electrode 121). As shown, the protrusions (also referred to as bumpy shapes) extend from the periphery surface. That is, the surface of the periphery has protrusions. For example, both the third planarization layer 115c and the anode electrode 121 have a periphery surface having protrusions with ridges and valleys.

In the present disclosure, the second area 121b of the anode electrode 121 is a part having a side-mirror shape and may configure the side-mirror structure (also referred to as the “SM structure”). The SM structure of the anode electrode 121 may be configured in the first open area OA1. For example, the SM structure of the anode electrode 121 may form a reflective emission area EA2. For example, the reflective emission area EA2 follows an outline of the main emission area EA1 and may have a continuous ring shape or a ring shape with breaks. In the case of the ring shape with breaks, the reflective emission area may enclose the outline of the main emission area EA1 and have breaks in the middle.

According to the first exemplary embodiment of the present disclosure, the side portion of the third planarization layer 115c has a bumpy shape, such as an iris or wavy pattern. Therefore, the second area 121b of the anode electrode 121 deposited thereon may also have a bumpy shape, such as an iris or wavy pattern. Therefore, a side mirror, that is, the second area 121b of the anode electrode 121 has an increased area so that the luminous efficiency may be improved and the luminance viewing angle may be improved.

As described above, the SM structure configured by the first open area OA1 forms the reflective emission area EA2. A part of light emitted by the light emitting diode 120 is reflected from the second area 121b of the anode electrode 121 by the SM structure to form a ring-shaped reflective emission area EA2. Therefore, the luminous efficiency may be improved.

Further, for example, the edge of the reflective emission area EA2 may have a bumpy shape, such as an iris or wavy pattern in accordance with the shapes of the side portion of the third planarization layer 115c and the second area 121b of the anode electrode 121. According to the first exemplary embodiment of the present disclosure, the side portion of the third planarization layer 115c and the second area 121b of the anode electrode 121 are formed to have a bumpy shape, such as an iris or wavy pattern. Therefore, the periodicity of the pattern is reduced to improve the concentric rainbow mura by the irregular reflection.

Here, referring to FIG. 7A, in the case of the comparative embodiment that the SM structure of the present disclosure is not applied, it is understood that only one main emission area EA1 is present. Referring to FIG. 7B, in the case of the comparative embodiment that the SM structure is applied, but the side portion of the third planarization layer has a circular shape, it is understood that the reflective emission area EA2 is present by the SM structure, in the vicinity of the main emission area EA1. Further, in the case of the first exemplary embodiment that the SM structure according to the present disclosure is applied and the side portion of the third planarization layer 115c has a bumpy shape, such as an iris or wavy pattern, referring to FIG. 8, it is understood that there may be a reflective emission area EA2 having a bumpy edge, such as an iris or wavy pattern, in the vicinity of the main emission area EA1, in accordance with the shape of the side portion of the third planarization layer 115c.

For example, in the case of the first exemplary embodiment of the present disclosure, the main emission area EA1 may have an approximately circular shape and the non-emission area NEA may have an approximately circular ring shape enclosing the main emission area EA1. For example, an inside of the reflective emission area EA2 may have an approximately circular ring shape and an outside may have a bumpy shape such as an iris or wavy pattern.

Referring to FIGS. 5, 6A, 6B, and 8, again, the anode electrode 121 extends from the second area 121b to include a third area 121c having a surface substantially parallel to a surface of the second substrate 110b. The third area 121c may correspond to the top surface of the third planarization layer 115c.

As described above, in one sub pixel, the second planarization layer 115b and the third planarization layer 115c may include at least one contact hole CNT spaced apart from the first open area OA1. Therefore, the driving transistor Td and the anode electrode 121 of the light emitting diode 120 may be electrically connected through a contact hole CNT.

Referring to FIGS. 4 and 5, the anode electrode 121 may include a third area 121c which extends from a side portion to a top surface of the second planarization layer 115b. At this time, an end of the third area 121c which is an end of the anode electrode 121 may have a bumpy shape, as seen from the plane. At this time, a shape of the end of the anode electrode 121 may be a bumpy shape, corresponding to the shape of the first open area OA1. As described above, when the first open area OA1 has a bumpy edge formed of an iris or wavy pattern, the end of the anode electrode 121 may have a shape corresponding to the bumpy shape of the first open area OA1. Referring to FIG. 4, the end of the anode electrode 121 may have a bumpy shape formed along a bumpy outline of the first open area OA1.

At this time, a width W of the third area 121c of the anode electrode 121 may be constant. That is, a width W of the third area 121c of the anode electrode 121 formed on the top surface of the third planarization layer 115c may be constant. However, a part of the anode electrode 121 which extends to be electrically connected to the driving transistor Td is excluded. As described above, the end of the anode electrode 121 may have a shape corresponding to the bumpy shape of the first open area OA1 so that a width of the third area 121c which is a part of the anode electrode 121 extending from the side portion to the top surface of the third planarization layer 115c may be constant. However, it is not limited thereto. Further, a boundary of the side portion of the second planarization layer 115b and an end of the third area 121c which is an end of the anode electrode 121 may be parallel to each other, but is not limited thereto.

The width W of the third area 121c of the anode electrode 121 may be designed to be reduced or minimized. The third area 121c of the anode electrode 121 may be formed to have a minimum width in consideration of the process margin.

According to the first exemplary embodiment of the present disclosure, a width of an extending part of the anode electrode 121 disposed on the top surface of the third planarization layer 115c is reduced or minimized to improve the concentric rainbow mura. That is, a width of the third area 121c of the anode electrode 121 disposed on the top surface of the third planarization layer 115c is reduced or minimized and the shape of the end of the anode electrode 121 may be formed to have a bumpy shape corresponding to the shape of the first open area OA1. By doing this, the margin of the anode electrode 121 is reduced or minimized to improve the rainbow mura.

The bank 116 may be disposed to cover the anode electrode 121.

The bank 116 may cover the second area 121b and the third area 121c of the anode

electrode 121. Further, the bank 116 may cover a part of the first area 121a of the anode electrode 121. For example, the bank 116 may cover a part of the edge of the first area 121a of the anode electrode 121.

A part of the bank 116 corresponding to an emission area of the sub pixel may be open.

For example, the bank 116 may include a second open area OA2 obtained by removing (opening) a part corresponding to the main emission area EA1 of each sub pixel. For example, the first open area OA1 may have a larger width than that of the second open area OA2. For example, as seen from the plane, the second open area OA2 may have a circular shape (see FIG. 6B), but is not limited thereto. The edge of the second open area OA2 of the present disclosure may have a bumpy shape formed of an iris or wavy pattern, or a plurality of polygonal patterns, or various shapes such as oval shape or a rectangular shape.

In the meantime, the main emission area EA1 may have a shape corresponding to a shape of the second open area OA2. When a shape of an arbitrary component corresponds to a shape of the other component, it means that the shape of the arbitrary component has the same shape as the other component, or has the same shape, but has a different size, or a shape of the arbitrary component is formed by transferring the shape of the other component by an arbitrary method. Accordingly, the shape of the main emission area EA1 is substantially understood to be obtained by transferring a shape of the second open area OA2 by light emitted from the organic layer 122 located in the second open area OA2.

The reflective emission area EA2 may not overlap the main emission area EA1 and may be located by enclosing the main emission area EA1.

Further, the reflective emission area EA2 may be a closed curve which encloses the main emission area EA1. Alternatively, the reflective emission area EA2 may have a shape of the closed curve which partially has a break.

The sub pixels may be divided by the main emission area EA1.

Next, the bank 116 may include a top surface, a side portion, and a bottom surface.

For example, the top surface of the bank 116 is a surface located at the top of the bank 116 and may be substantially parallel to the second substrate 110b. Further, the top surface of the bank 116 may correspond to the top surface of the third planarization layer 115c.

A side portion of the bank 116 may be a surface extending from the top surface of the bank 116 to a side surface. The side portion of the bank 116 may have a selected taper angle. For example, the side portion of the bank 116 may have a taper angle of 30° to 65°, but is not limited thereto. The side portion of the bank 116 may correspond to the side portion of the third planarization layer 115c.

For example, the bottom surface of the bank 116 may correspond to a surface which abuts with the anode electrode 121 in the first area 121a of the anode electrode 121. The bottom surface of the bank 116 may correspond to a non-emission area NEA between the main emission area EA1 and the reflective emission area EA2.

The first open area OA1 provided in the third planarization layer 115c may have a width larger than that of the second open area OA2 provided in the bank 116. Therefore, the second open area OA2 may be located in the first open area OA1.

For example, a part of the anode electrode 121 may be exposed by the second open area OA2.

The bank 116 may be formed of a PI-based material, but is not limited thereto. Further, the bank 116 may further include a black material to improve the rainbow mura.

A side portion of the bank 116 may have the circular shape, like the edge of the second open area OA2 (see FIG. 6B), but the present disclosure is not limited thereto. For example, the side portion of the bank 116 of the present disclosure may have a bumpy shape formed of an iris or wavy pattern, or a plurality of polygonal patterns, or various shapes such as oval shape or a rectangular shape.

For example, the organic layer 122 may be disposed in the second open area OA2 of the bank 116 and in the vicinity thereof. For example, the organic layer 122 may be disposed on the anode electrode 121 exposed through the second open area OA2 of the bank 116. For example, the organic layer 122 may be disposed in the second open area OA2 of the bank 116.

The organic layer 122 may be disposed only in the second open area OA2, but the present disclosure is not limited thereto and a part thereof may also be disposed on a top surface and a side portion of the bank 116 other than the second open area OA2.

The cathode electrode 123 may be disposed on the organic layer 122.

As described above, the light emitting diode 120 may be configured by the anode electrode 121, the organic layer 122, and the cathode electrode 123.

For example, the main emission area EA1 may be formed by the light emitting diode 120 provided in the second open area OA2.

Referring to FIG. 5, the planarization layer includes a first side surface FSS and a second side surface SSS opposite the first side surface FSS and a bottom surface BS between the first side surface FSS and the second side surface SSS. In fact, the planarization layer includes a plurality of planarization layers and here, the third planarization layer 115c is disposed on top of the second planarization layer 115b, and the second planarization layer 115b is disposed on top of the first planarization layer 115a. Accordingly, the first side surface FSS mentioned above refers to the first side surface of the third planarization layer 115c and the second side surface SSS mentioned above refers to the second side surface of the third planarization layer 115c. The bottom surface BS mentioned above refers to the top surface of the second planarization layer 115b that is exposed by the first open area OA1.

As shown, the anode electrode continuously and contiguously extends along the first side surface FSS of the third planarization layer 115c, the top surface BS of the second planarization layer 115b, and the second side surface SSS of the third planarization layer 115c.

In some embodiments, the first open area OA1 is within an area defined by the bottom surface BS and the first and second side surfaces FSS, SSS.

Referring to FIG. 5, the bank 116 includes a first upper surface FUS, a first side wall FSW extending from the first upper surface FUS, a second upper surface SUS, and a second side wall SSW extending from the second upper surface SUS. Here, the second side wall SSW is opposite and facing the first side wall FSW. Further, the first upper surface FUS is spaced apart from the second upper surface SUS. The second open area OA2 is between the first upper surface FUS and the second upper surface SUS.

As shown, the cathode electrode 123 continuously and contiguously extends along the first upper surface FUS, the first side wall FSW, a top surface of the organic layer 122, the second side wall SSW, and the second upper surface SUS of the bank 116.

In some embodiments, the second open area OA2 is within an area defined by the first side wall FSW and the second side wall SSW of the bank 116.

In some embodiments, the organic layer 122 is spaced apart from the first side surface FSS of the third planarization layer 115c and the second side surface SSS of the third planarization layer 115c.

In some embodiments, the cathode electrode 123 is spaced apart from the first side surface FSS of the third planarization layer 115c and the second side surface SSS of the third planarization layer 115c.

In some embodiments, the anode electrode 121 at the first side surface FSS of the third planarization layer 115c (e.g., the 121b portion) is spaced apart from the cathode electrode 123 at the first side wall FSW of the bank 116.

As shown in FIGS. 4 and 9, the first side surface FSS of the third planarization layer 115c and the second side surface SSS of the third planarization layer 115c have a bumpy shape seen from a plan view. Further, the anode electrode 121 at the first side surface FSS of the third planarization layer 115c and the anode electrode 121 at the second side surface SSS of the third planarization layer 115c have a bumpy shape seen from a plan view.

In some embodiments, the second open area OA2 overlaps with a main emission area from a plan view. The anode electrode 121 at the first side surface FSS of the third planarization layer 115c and the anode electrode 121 at the second side surface SSS of the third planarization layer 115c overlaps with a reflective emission area from a plan view. A non-emission area NEA is between the main emission area EA1 and the reflective emission area EA2 from a plan view.

An encapsulation layer may be disposed above the above-described light emitting diode 120.

The encapsulation layer may have a single layer structure or a multi-layered structure. For example, the encapsulation layer may include a first encapsulation layer, a second encapsulation layer, and a third encapsulation layer.

For example, the first encapsulation layer and the third encapsulation layer may be configured by an inorganic layer and the second encapsulation layer may be configured by an organic layer. For example, among the first encapsulation layer, the second encapsulation layer, and the third encapsulation layer, the second encapsulation layer is the thickest, so that the second encapsulation layer may serve as a planarization layer.

The first encapsulation layer may be formed by the inorganic insulating material which can be subjected to the low temperature deposition, and for example, may be configured by silicon nitride SiNx, silicon oxide SiOx, silicon oxynitride SiON, or aluminum oxide Al₂O₃.

The second encapsulation layer may be formed to have a smaller area than that of the first encapsulation layer. In this case, the second encapsulation layer may be formed to expose both ends of the first encapsulation layer.

Further, for example, the second encapsulation layer may be configured by an organic insulating material, such as acrylic resin, epoxy resin, polyimide, polyethylene, or silicon oxy carbon (SiOC). Further, for example, the second encapsulation layer may be formed by an inkjet method, but is not limited thereto.

The third encapsulation layer may be formed to cover a top surface and a side surface of each of the second encapsulation layer and the first encapsulation layer.

For example, the third encapsulation layer may minimize or block penetration of external moisture or oxygen into the first encapsulation layer and the second encapsulation layer. Further, for example, the third encapsulation layer may be configured by an inorganic insulating material, such as silicon oxide SiOx, silicon oxynitride SiON, or aluminum oxide Al₂O₃, or silicon nitride SiNx.

A touch sensor layer may be disposed above the above-described encapsulation layer.

In the meantime, as described above, as seen from the plane, a side portion of the third planarization layer and an edge of the first open area may have a bumpy shape configured by a plurality of polygonal patterns, which will be described in more detail with reference to the drawing.

FIG. 9 is a view illustrating a sub pixel structure of a second exemplary embodiment of the present disclosure;

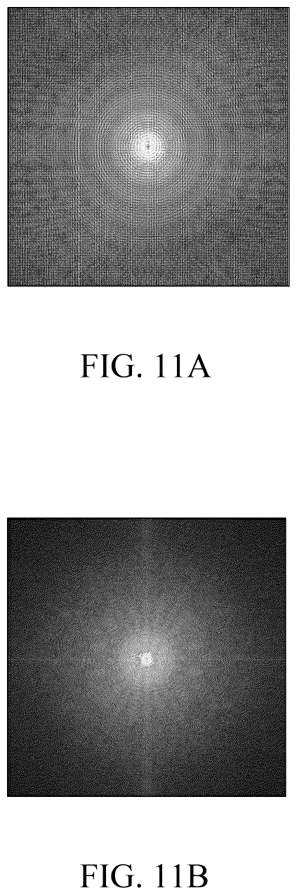

FIG. 10 is a view exemplarily illustrating an emission image according to a second exemplary embodiment of the present disclosure.

In a second exemplary embodiment of the present disclosure of FIGS. 9 and 10, only shapes of a third planarization layer 215c and a first open area OA1 are different from those of the first exemplary embodiment of the present disclosure of FIGS. 4 to 8 described above. However, the other configurations are substantially the same so that a redundant description will be omitted.

FIG. 9 illustrate a part of a display panel in which five sub pixels SP1, SP2, and SP3 are disposed as an example and exemplarily illustrates a bank 116 including a second open area OA2 which is an emission area, an anode electrode 121, and a third planarization layer 215c.

FIG. 10 illustrates a part of a cross section of one sub pixel of a display panel according to a second exemplary embodiment of the present disclosure and an emission image corresponding thereto as an example. Even though in FIG. 10, components above and below the light emitting diode 120 are not illustrated for the convenience of description, the present disclosure is not limited thereto and the present disclosure may include an encapsulation layer and a touch sensor layer above the light emitting diode 120.

Referring to FIG. 9, the display panel according to the second exemplary embodiment of the present disclosure may include a pixel area in which a plurality of sub pixels SP1, SP2, and SP3 is provided and a wiring area in which various signal lines are disposed.

A plurality of first sub pixels SP1, second sub pixels SP2, and third sub pixels SP3 may be disposed in the pixel area.

For example, the first sub pixel SP1 may be a red sub pixel.

For example, the second sub pixel SP2 may be a green sub pixel.

For example, the third sub pixel SP3 may be a blue sub pixel.

For example, the first sub pixel SP1, the second sub pixel SP2, and the third sub pixel SP3 may have a circular shape or a polygonal shape, but are not limited thereto. Here, shapes of the sub pixels SP1, SP2, and SP3 are defined by the shape of the anode electrode 121, but the present disclosure is not limited thereto.

In FIG. 9, it is illustrated that one first sub pixel SP1, one second sub pixel SP2, and one third sub pixel SP3 are gathered to configure one pixel, but is not limited thereto.

In the meantime, according to the present disclosure, due to the side mirror SM structure of the anode electrode 121, a reflective emission area is added as well as a main emission area so that the emission area may be expanded as compared with each of the sub pixels SP1, SP2, and SP3.

Further, according to a second exemplary embodiment of the present disclosure, a side portion of the third planarization layer 215c which is abut with a side surface of the anode electrode 121 having a side mirror structure has a bumpy shape formed by a plurality of triangular patterns, as seen from the plane. Therefore, an area of the side mirror of the anode electrode 121 may be substantially increased. By doing this, a luminous efficiency may be improved, a luminance viewing angle may be improved, and a concentric rainbow mura may be improved by the irregular reflection. However, the present disclosure is not limited thereto and a side portion of the third planarization layer 215c may have a bumpy shape formed by different polygonal patterns such as a plurality of quadrangles or pentagons.

Referring to FIG. 10, the connection electrode 125 may be disposed on the first planarization layer 115a.

The second planarization layer 115b may be disposed on the connection electrode 125.

A third planarization layer 215c may be disposed on the second planarization layer 115b.

For example, the third planarization layer 215c may include a first open area OA1 obtained by removing (opening) a part corresponding to a main emission area EA1, a reflective emission area EA2, and a non-emission area NEA of the sub pixel.

For example, as seen from the plane, the first open area OA1 has an approximately circular shape with a bumpy edge formed by a plurality of triangular patterns, but is not limited thereto. The edge of the first open area OA1 of the present disclosure may have a bumpy shape formed of different polygonal patterns, such as a plurality of quadrangles or pentagons.

The third planarization layer 215c may include a top surface and a side portion.

The top surface of the third planarization layer 215c is a surface located at the top of the third planarization layer 215c and may be substantially parallel to the second substrate 110b.

Further, the side portion of the third planarization layer 215c is a surface extending from the top surface of the third planarization layer 215c to a side surface. For example, a side portion of the third planarization layer 215c may have a selected taper angle. For example, a side portion of the third planarization layer 215c may have a taper angle of 30° to 65°, but is not limited thereto.

As seen from the plane, the side portion of the third planarization layer 215c may have a bumpy shape formed of the plurality of triangular patterns, like the edge of the first open area OA1, but is not limited thereto. A side portion of the third planarization layer 215c of the present disclosure may have a bumpy shape formed by different polygonal patterns such as a plurality of quadrangles or pentagons.

In the meantime, the anode electrode 121 may be disposed on the top surface and the side portion of the third planarization layer 215c and on the second planarization layer 115b. For example, the anode electrode 121 may be disposed on the first open area OA1 and the top surface and the side portion of the third planarization layer 215c.

For example, the anode electrode 121 which is disposed in the first open area OA1 may be in contact with the top surface of the second planarization layer 115b.

For example, the anode electrode 121 may include a first area 121a which has a surface substantially parallel to a surface of the second substrate 110b in the first open area OA1 and a second area 121b which extends from the first area 121a so that a surface has a selected angle with respect to the second substrate 110b. Further, for example, the first area 121a of the anode electrode 121 may correspond to the first open area OA1. For example, the second area 121b of the anode electrode 121 may correspond to a side portion of the third planarization layer 215c.

In the present disclosure, the second area 121b of the anode electrode 121 is a part having a side-mirror shape and may configure the SM structure. The SM structure of the anode electrode 121 may be configured in the first open area OA1. For example, the SM structure of the anode electrode 121 may form a reflective emission area EA2. For example, the reflective emission area EA2 follows an outline of the main emission area EA1 and may have a continuous ring shape or a ring shape with a break. In the case of the ring shape with a break, the reflective emission area may enclose the outline of the main emission area EA1 and have breaks in the middle.

For example, in the case of the second exemplary embodiment of the present disclosure, the main emission area EA1 may have an approximately circular shape and the non-emission area NEA may have an approximately circular ring shape enclosing the main emission area EA1. For example, an inside of the reflective emission area EA2 may have an approximately circular ring shape and an outside may have a bumpy shape formed of a plurality of triangular patterns.

According to the second exemplary embodiment of the present disclosure, the side portion of the third planarization layer 215c has a bumpy shape formed of a plurality of triangular patterns. Therefore, the second area 121b of the anode electrode 121 deposited thereon may also have a bumpy shape formed of a plurality of triangular patterns. Therefore, as an area of a side mirror, that is, the second area 121b of the anode electrode 121 is increased, the luminous efficiency may be improved and the luminance viewing angle may be improved. However, the present disclosure is not limited thereto and the second area 121b of the anode electrode 121 may have a bumpy shape formed by different polygonal patterns such as a plurality of quadrangles or pentagons.

As described above, the SM structure configured by the first open area OA1 forms the reflective emission area EA2. A part of light emitted by the light emitting diode 120 is reflected from the second area 121b of the anode electrode 121 by the SM structure to form a ring-shaped reflective emission area EA2. Therefore, the luminous efficiency may be improved.

Further, for example, an edge of the reflective emission area EA2 may have a bumpy shape formed of a plurality of triangular patterns according to the shape of the side portion of the third planarization layer 215c. As described above, in the second exemplary embodiment of the present disclosure, the side portion of the third planarization layer 215c is formed to have a bumpy shape formed of a plurality of triangular patterns so that the periodicity of the pattern is reduced to improve the concentric rainbow mura by the irregular reflection.

In the meantime, the anode electrode 121 may include a third area 121c which extends from the second area 121b so that a surface is substantially parallel to a surface of the second substrate 110b. The third area 121c may correspond to the top surface of the third planarization layer 215c.

As described above, in one sub pixel, the second planarization layer 115b and the third planarization layer 215c may include at least one contact hole CNT spaced apart from the first open area OA1. Therefore, the driving transistor Td and the anode electrode 121 of the light emitting diode 120 may be electrically connected through a contact hole CNT.

Referring to FIGS. 9 and 10, the anode electrode 121 may include a third area 121c which extends from a side portion to a top surface of the second planarization layer 115b. At this time, an end of the third area 121c which is an end of the anode electrode 121 may have a bumpy shape, as seen from the plane. At this time, a shape of the end of the anode electrode 121 may be a bumpy shape, corresponding to the shape of the first open area OA1. As described above, when the first open area OA1 has a bumpy edge formed of a polygonal shape, the end of the anode electrode 121 may have a shape corresponding to the bumpy shape of the first open area OA1. Referring to FIG. 4, the end of the anode electrode 121 may have a bumpy shape formed along a bumpy outline of the first open area OA1.

At this time, a width of the third area 121c of the anode electrode 121 may be constant. That is, a width of the third area 121c of the anode electrode 121 formed on the top surface of the second planarization layer 115b may be constant. However, a part of the anode electrode 121 which extends to be electrically connected to the driving transistor Td is excluded. As described above, the end of the anode electrode 121 has a shape corresponding to the bumpy shape of the first open area OA1 so that a width of the third area 121c which is a part of the anode electrode 121 extending from the side portion to the top surface of the second planarization layer 115b may be constant. However, it is not limited thereto. Further, a boundary of the side portion of the second planarization layer 115b and an end of the third area 121c which is an end of the anode electrode 121 may be parallel to each other, but is not limited thereto.

The width of the third area 121c of the anode electrode 121 may be designed to be reduced or minimized. The third area 121c of the anode electrode 121 may be formed to have a minimum width in consideration of the process margin.

According to the second exemplary embodiment of the present disclosure, a width of an extending part of the anode electrode 121 disposed on the top surface of the second planarization layer 115b is reduced or minimized to improve the concentric rainbow mura. That is, a width of the third area 121c of the anode electrode 121 disposed on the top surface of the second planarization layer 115b is reduced or minimized and the shape of the end of the anode electrode 121 may be formed to have a bumpy shape corresponding to the shape of the first open area OA1. By doing this, the margin of the anode electrode 121 is reduced or minimized to improve the rainbow mura.

The bank 116 may be disposed to cover the anode electrode 121.

The bank 116 may cover the second area 121b and the third area 121c of the anode electrode 121. Further, the bank 116 may cover a part of the first area 121a of the anode electrode 121. For example, the bank 116 may cover a part of the edge of the first area 121a of the anode electrode 121.

A part of the bank 116 corresponding to an emission area of the sub pixel may be open.

For example, the bank 116 may include a second open area OA2 obtained by removing (opening) a part corresponding to the main emission area EA1 of each sub pixel. For example, the first open area OA1 may have a larger width than that of the second open area OA2. For example, as seen from the plane, the second open area OA2 may have a circular shape, but the present disclosure is not limited thereto. The edge of the second open area OA2 of the present disclosure may have a bumpy shape formed of an iris or wavy pattern, or a plurality of polygonal patterns, or various shapes such as oval shape or a rectangular shape.

The bank 116 may include a top surface, a side portion, and a bottom surface.

For example, the top surface of the bank 116 is a surface located at the top of the bank 116 and may be substantially parallel to the second substrate 110b. Further, the top surface of the bank 116 may correspond to the top surface of the third planarization layer 215c.

A side portion of the bank 116 is a surface extending from the top surface of the bank 116 to a side surface. The side portion of the bank 116 may have a selected taper angle. For example, the side portion of the bank 116 may have a taper angle of 30° to 65°, but is not limited thereto. The side portion of the bank 116 may correspond to the side portion of the third planarization layer 215c.

For example, the bottom surface of the bank 116 may correspond to a surface of the first area 121a of the anode electrode 121 which abuts with the anode electrode 121. The bottom surface of the bank 116 may correspond to a non-emission area NEA between the main emission area EA1 and the reflective emission area EA2.

The first open area OA1 provided in the third planarization layer 215c may have a width larger than that of the second open area OA2 provided in the bank 116. Therefore, the second open area OA2 may be located in the first open area OA1.

For example, a part of the anode electrode 121 may be exposed by the second open area OA2.

A side portion of the bank 116 may have the circular shape, like the edge of the second open area OA2, but the present disclosure is not limited thereto. For example, the side portion of the bank 116 of the present disclosure may have a bumpy shape formed of an iris or wavy pattern, or a plurality of polygonal patterns.

For example, the organic layer 122 may be disposed in the second open area OA2 of the bank 116 and in the vicinity thereof. For example, the organic layer 122 may be disposed on the anode electrode 121 exposed through the second open area OA2 of the bank 116. For example, the organic layer 122 may be disposed in the second open area OA2 of the bank 116.

The organic layer 122 may be disposed only in the second open area OA2, but the present disclosure is not limited thereto and a part thereof may also be disposed on a top surface and a side portion of the bank 116 other than the second open area OA2.

The cathode electrode 123 may be disposed on the organic layer 122.

As described above, the light emitting diode 120 may be configured by the anode electrode 121, the organic layer 122, and the cathode electrode 123.

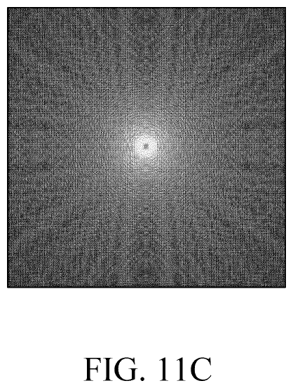

FIGS. 11A to 11C are views illustrating a mura image.

FIGS. 11A to 11C illustrates mura images by the reflection of external light according to the simulation as examples.

FIG. 11A illustrates a mura image of a comparative embodiment in which a side portion of the third planarization layer has a circular shape, as an example. FIG. 11B illustrates a mura image of a first exemplary embodiment in which a side portion of a third planarization layer and a second area 121b of an anode electrode 121 have a bumpy shape such as an iris or wavy pattern, as an example. FIG. 11C illustrates a mura image of a second exemplary embodiment in which a side portion of a third planarization layer and a second area 121b of an anode electrode 121 have a bumpy shape formed of a plurality of triangular patterns, as an example.

First, referring to FIG. 11A, in the case of the comparative embodiment in which the side portion of the third planarization layer has a circular shape, a concentric rainbow mura caused by the interference is identified.

In contrast, referring to FIGS. 11B and 11C, in the first exemplary embodiment in which a side portion of a third planarization layer and a second area 121b of an anode electrode 121 have a bumpy shape such as an iris or wavy pattern and the second exemplary embodiment in which a side portion of a third planarization layer and a second area 121b of an anode electrode 121 have a bumpy shape formed of a plurality of triangular patterns, the circular interference is not identified.

As described above, according to the exemplary embodiments of the present disclosure, the periodicity of the edge pattern of the side portion of the third planarization layer and the second area 121b of the anode electrode 121 is reduced so that the concentric rainbow mura may be improved by the irregular reflection.

In the meantime, the sub pixels of the present disclosure may have different shapes so that the anode electrode and the first open area and the second open area may have different shapes, which will be described in detail with reference to the drawing.

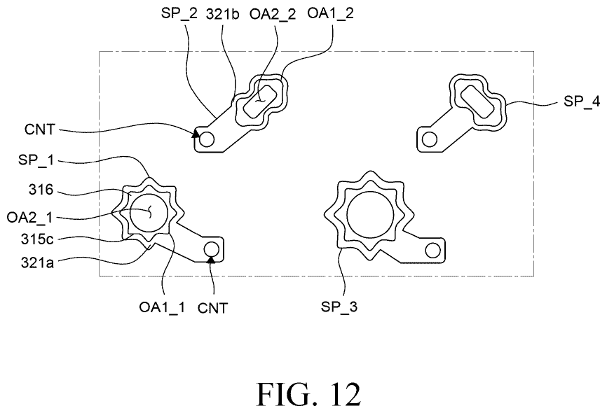

FIG. 12 is a view illustrating a sub pixel structure of a third exemplary embodiment of the present disclosure.

A third exemplary embodiment of the present disclosure of FIG. 12 is configured by sub pixels SP_1, SP_2, SP_3, and SP_4 having different shapes, which is different from the above-described exemplary embodiments, but the other configurations are substantially the same so that a redundant description will be omitted.

FIG. 12 illustrates a part of a display panel in which four sub pixels SP_1, SP_2, SP_3, and SP_4 are disposed as an example and exemplarily illustrates a bank 316 including second open areas OA2_1 and OA2_2, anode electrodes 321a and 321b, and a third planarization layer 315c.

In FIG. 12, for the convenience of description, only a part of a configuration of a first type sub pixel SP_1 and a second type sub pixel SP_2 will be described by referring to reference numerals.

Referring to FIG. 12, the display panel according to the third exemplary embodiment of the present disclosure may include a pixel area in which a plurality of sub pixels SP_1, SP_2, SP_3, and SP_4 is provided and a wiring area in which various signal lines are disposed.

For example, in the pixel area, a plurality of first type sub pixels SP_1, second type sub pixels SP_2, third type sub pixels SP_3, and fourth type sub pixels SP_4 may be disposed.

The plurality of first type sub pixels SP_1, second type sub pixels SP_2, third type sub pixels SP_3, and fourth type sub pixels SP_4 may have different shapes, but may have substantially the same configuration.

For example, the first type sub pixels SP_1 may be a red, green, or blue sub pixel.

For example, the second type sub pixels SP_2 may be a red, green, or blue sub pixel.

For example, the third type sub pixels SP_3 may be a red, green, or blue sub pixel.

For example, the fourth type sub pixels SP_4 may be a red, green, or blue sub pixel.

For example, the first type sub pixels SP_1 and the third type sub pixels SP_3 may have an approximately circular shape, but the present disclosure is not limited thereto.

For example, the second type sub pixels SP_2 and the fourth type sub pixels SP_4 may have an approximately oval shape or rectangular shape, but the present disclosure is not limited thereto.

Here, shapes of the sub pixels SP_1, SP_2, SP_3, and SP_4 are defined by shapes of the anode electrodes 321a and 321b, but the present disclosure is not limited thereto.

In the meantime, according to the present disclosure, the anode electrodes 321a and 321b have the side mirror SM structure so that a reflective emission area is added as well as a main emission area so that each emission area may be expanded as compared with each of the sub pixels SP_1, SP_2, SP_3, and SP_4.

In the third exemplary embodiment of the present disclosure, the first type sub pixel SP_1 may include a first anode electrode 321a and the second type sub pixel SP_2 may include a second anode electrode 321b.

For example, the third planarization layer 315c may include first open areas OA1_1 and OA1_2 obtained by removing (opening) a part corresponding to a main emission area, a reflective emission area, and a non-emission area of the sub pixel. The first open areas OA1_1 and OA1_2 may include a first type of first open area OA1_1 of the first type sub pixel SP_1 and a second type of first open area OA1_2 of the second type sub pixel SP_2.

As seen from the plane, the first type of first open area OA1_1 may have an approximately circular shape with a bumpy edge such as an iris or wavy pattern, but is not limited thereto. For example, the edge of the first type of first open area OA1_1 may have a bumpy shape formed of a plurality of polygonal patterns.

As seen from the plane, the second type of first open area OA1_2 may have an approximately oval shape or rectangular shape with a bumpy edge such as an iris or wavy pattern, but is not limited thereto. For example, the edge of the second type of first open area OA1_2 may have a bumpy shape configured by a plurality of polygonal patterns.

Further, for example, in the first type sub pixel SP_1, one side portion of the third planarization layer 315c which is opposite to the first type of first open area OA1_1 may have a bumpy shape such as an iris or wavy pattern, like the edge of the first type of first open area OA1_1. as seen from the plane, but the present disclosure is not limited thereto. One side portion of the third planarization layer 315c may have a bumpy shape configured by a plurality of polygonal patterns.

Further, for example, in the second type sub pixel SP_2, the other side portion of the third planarization layer 315c which is opposite to the second type of first open area OA1_2 may have a bumpy shape such as an iris or wavy pattern, like the edge of the second type of first open area OA1_2, as seen from the plane, but the present disclosure is not limited thereto. The other one side portion of the third planarization layer 315c may have a bumpy shape configured by a plurality of polygonal patterns.

According to the third exemplary embodiment of the present disclosure, one side portion of the third planarization layer 315c has a bumpy shape, such as iris or wavy pattern. Therefore, the second area of the first anode electrode 321a deposited thereon may also have a bumpy shape, such as iris or wavy pattern as seen from the plane. However, the present disclosure is not limited thereto and the second area of the first anode electrode 321a of the present disclosure may have a bumpy shape formed of a plurality of polygonal patterns.

According to the third exemplary embodiment of the present disclosure, the other side portion of the third planarization layer 315c has a bumpy shape, such as iris or wavy pattern. Therefore, the second area of the second anode electrode 321b deposited thereon may also have a bumpy shape, such as iris or a wavy pattern as seen from the plane. However, the present disclosure is not limited thereto and the second area of the second anode electrode 321b of the present disclosure may have a bumpy shape formed of a plurality of polygonal patterns.

Further, shapes of the ends of the first anode electrode 321a and the second anode electrode 321b may be a bumpy shape corresponding to the shape of the first open area OA1. As described above, when the first open area OA1 has a bumpy edge formed of an iris or wavy pattern, the ends of the first anode electrode 321a and the second anode electrode 321b may have a shape corresponding to the bumpy shape of the first open area OA1. Referring to FIG. 12, the end of the anode electrode 321 may have a bumpy shape formed along a bumpy outline of the first open area OA1. That is, the ends of the first anode electrode 321a and the second anode electrode 321b may have the same shape as the bumpy shape of the first open area OA1.

At this time, widths of the first anode electrode 321a and the second anode electrode 321b formed along a bumpy outline of the first open area OA1 may be constant. Further, a boundary of the side portion of the second planarization layer 315b and ends of the first anode electrode 321a and the second anode electrode 321b may be parallel to each other, but the present disclosure is not limited thereto. A width of the end of the anode electrode 321 may be designed to be reduced or minimized. That is, ends of the first anode electrode 321a and the second anode electrode 321b may be formed to have a minimum width in consideration of a process margin.

For example, the bank 316 may include second open areas OA2_1 and OA2_2 obtained by removing (opening) a part corresponding to the main emission area of each of sub pixels SP_1, SP_2, SP_3, and SP_4. For example, the first open areas OA1_1 and OA1_2 may have a larger width than that of the second open areas OA2_1 and OA2_2. The second open areas OA2_1 and OA2_2 may include a first type of second open area OA2_1 of the first type sub pixel SP_1 and a second type of second open area OA2_2 of the second type sub pixel SP_2.

As seen from the plane, the first type of second open area OA2_1 may have an approximately circular shape with a bumpy edge such as an iris or a wavy pattern, but is not limited thereto. For example, the edge of the first type of second open area OA2_1 may have a bumpy shape formed of a plurality of polygonal patterns.

As seen from the plane, the second type of second open area OA2_2 may have an approximately oval shape or rectangular shape with a bumpy edge such as an iris or a wavy pattern, but is not limited thereto. For example, the edge of the second type of second open area OA2_2 may have a bumpy shape configured by a plurality of polygonal patterns.

Further, for example, in the first type sub pixel SP_1, one side portion of the bank 316 which is opposite to the first type of second open area OA2_1 may have a bumpy shape such as an iris or a wavy pattern, like the edge of the first type of second open area OA2_1, as seen from the plane, but the present disclosure is not limited thereto. One side portion of the bank 316 may have a bumpy shape configured by a plurality of polygonal patterns.

Further, for example, in the second type sub pixel SP_2, the other side portion of the bank 316 which is opposite to the second type of second open area OA2_2 may have a bumpy shape such as an iris or a wavy pattern, like the edge of the second type of second open area OA2_2, as seen from the plane, but the present disclosure is not limited thereto. For example, the other side portion of the bank 316 may have a bumpy shape configured by a plurality of polygonal patterns.

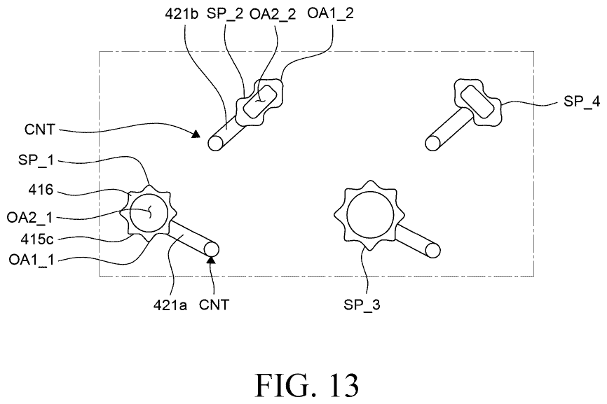

FIG. 13 is a view illustrating a sub pixel structure of a fourth exemplary embodiment of the present disclosure.

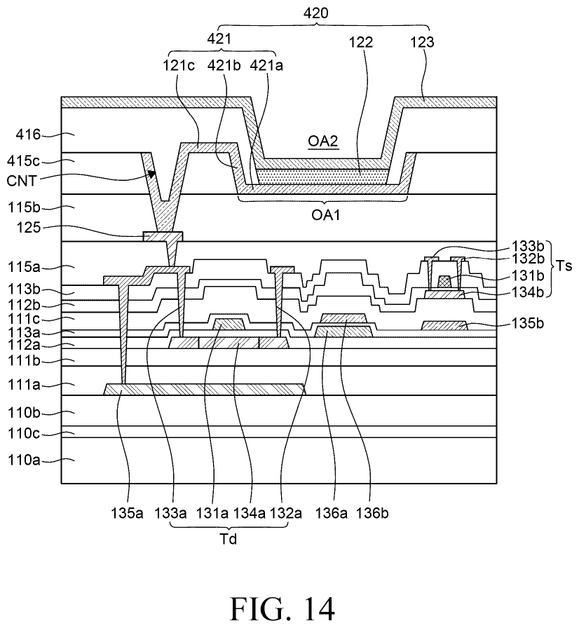

FIG. 14 is a view illustrating a cross-sectional structure of a display panel according to a fourth exemplary embodiment of the present disclosure.

In a fourth exemplary embodiment of the present disclosure of FIGS. 13 and 14, an anode electrode 421 has a different size from that in the above-described exemplary embodiments, but the other configurations are substantially the same so that a redundant description will be omitted.

FIG. 13 illustrates a part of a display panel in which four sub pixels SP_1, SP_2, SP_3, and SP_4 are disposed as an example and exemplarily illustrates a bank 416 including second open areas OA2_1 and OA2_2, anode electrodes 421a and 421b, and a third planarization layer 415c.

In FIGS. 13 and 14, for the convenience of description, only a part of a configuration of a first type sub pixel SP_1 and a second type sub pixel SP_2 will be described by referring to reference numerals.

Referring to FIGS. 13 and 14, the display panel according to the fourth exemplary embodiment of the present disclosure may include a pixel area in which a plurality of sub pixels SP_1. SP_2, SP_3, and SP_4 is provided and a wiring area in which various signal lines are disposed.

For example, in the pixel area, a plurality of first type sub pixels SP_1, second type sub pixels SP_2, third type sub pixels SP_3, and fourth type sub pixels SP_4 may be disposed.

The plurality of first type sub pixels SP_1, second type sub pixels SP_2, third type sub pixels SP_3, and fourth type sub pixels SP_4 may have different shapes, but may have substantially the same configuration.

For example, the first type sub pixels SP_1 may be a red, green, or blue sub pixel.

For example, the second type sub pixels SP_2 may be a red, green, or blue sub pixel.

For example, the third type sub pixels SP_3 may be a red, green, or blue sub pixel.

For example, the fourth type sub pixels SP_4 may be a red, green, or blue sub pixel.

For example, the first type sub pixels SP_1 and the third type sub pixels SP_3 may have an approximately circular shape, but the present disclosure is not limited thereto.

For example, the second type sub pixels SP_2 and the fourth type sub pixels SP_4 may have an approximately oval shape or rectangular shape, but the present disclosure is not limited thereto.

Here, shapes of the sub pixels SP_1, SP_2, SP_3, and SP_4 is defined by shapes of the anode electrodes 421a and 421b, but the present disclosure is not limited thereto.

In the meantime, according to the present disclosure, the anode electrodes 421a and 421b have the side mirror SM structure so that a reflective emission area is added as well as a main emission area so that each emission area may be expanded as compared with each of the sub pixels SP_1. SP_2, SP_3, and SP_4.

In the fourth exemplary embodiment of the present disclosure, the first type sub pixel SP_1 may include a first anode electrode 421a and the second type sub pixel SP_2 may include a second anode electrode 421b.

For example, the third planarization layer 415c may include first open areas OA1_1 and OA1_2 obtained by removing (opening) a part corresponding to a main emission area, a reflective emission area, and a non-emission area of the sub pixel. The first open areas OA1_1 and OA1_2 may include a first type of first open area OA1_1 of the first type sub pixel SP_1 and a second type of first open area OA1_2 of the second type sub pixel SP_2.

As seen from the plane, the first type of first open area OA1_1 may have an approximately circular shape with a bumpy edge such as an iris or wavy pattern, but is not limited thereto. For example, the edge of the first type of first open area OA1_1 may have a bumpy shape formed of a plurality of polygonal patterns.

As seen from the plane, the second type of first open area OA1_2 may have an approximately oval shape or rectangular shape with a bumpy edge such as an iris or wavy pattern, but is not limited thereto. For example, the edge of the second type of first open area OA1_2 may have a bumpy shape configured by a plurality of polygonal patterns.

Further, for example, in the first type sub pixel SP_1, one side portion of the third planarization layer 415c which is opposite to the first type of first open area OA1_1 may have a bumpy shape such as an iris or a wavy pattern, like the edge of the first type of first open area OA1_1, as seen from the plane, but the present disclosure is not limited thereto. One side portion of the third planarization layer 415c may have a bumpy shape configured by a plurality of polygonal patterns.

Further, for example, in the second type sub pixel SP_2, the other side portion of the third planarization layer 415c which is opposite to the second type of first open area OA1_2 may have a bumpy shape such as an iris or wavy pattern, like the edge of the second type of first open area OA1_2, but the present disclosure is not limited thereto. The other one side portion of the third planarization layer 415c may have a bumpy shape configured by a plurality of polygonal patterns.

According to the fourth exemplary embodiment of the present disclosure, one side portion of the third planarization layer 415c has a bumpy shape, such as iris or a wavy pattern. Therefore, the second area of the first anode electrode 421a deposited thereon may also have a bumpy shape, such as iris or wavy pattern as seen from the plane. However, the present disclosure is not limited thereto and the second area of the first anode electrode 421a of the present disclosure may have a bumpy shape formed of a plurality of polygonal patterns.

According to the fourth exemplary embodiment of the present disclosure, the other side portion of the third planarization layer 415c has a bumpy shape, such as iris or wavy pattern. Therefore, the second area of the second anode electrode 421b deposited thereon may also have a bumpy shape, such as iris or wavy pattern as seen from the plane. However, the present disclosure is not limited thereto and the second area of the second anode electrode 421b of the present disclosure may have a bumpy shape formed of a plurality of polygonal patterns.

Further, shapes of the ends of the first anode electrode 421a and the second anode electrode 421b may be a bumpy shape corresponding to the shape of the first open area OA1. As described above, when the first open area OA1 has a bumpy edge formed of iris or wavy pattern, the ends of the first anode electrode 421a and the second anode electrode 421b may have a shape corresponding to the bumpy shape of the first open area OA1. Referring to FIGS. 13 and 14, the end of the anode electrode 421 may have a bumpy shape formed along a bumpy outline of the first open area OA1. That is, the ends of the first anode electrode 421a and the second anode electrode 421b may have the same shape as the bumpy shape of the first open area OA1.

At this time, widths of the first anode electrode 421a and the second anode electrode 421b formed along a bumpy outline of the first open area OA1 may be constant. Further, a boundary of the side portion of the second planarization layer 415b and the end of the anode electrode 421 may be parallel to each other.

At this time, a boundary of a top surface of the third planarization layer 415c and ends of the first anode electrode 421a and the second anode electrode 421b coincide with each other. Therefore, a width of the end of the anode electrode 421 may be designed to be reduced or minimized. That is, the end of the anode electrode 421 may be formed to have a minimum width in consideration of the process margin.

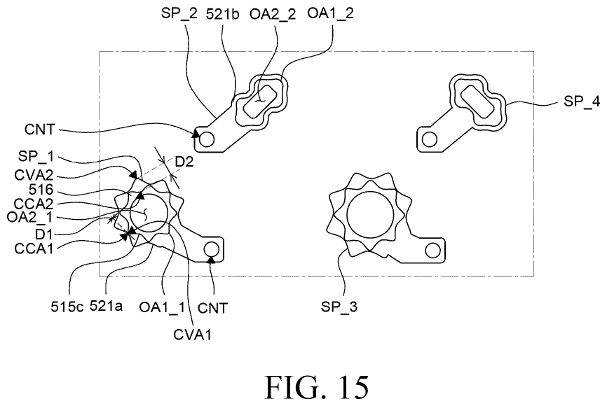

FIG. 15 is a view illustrating a sub pixel structure of a fifth exemplary embodiment of the present disclosure.

A fifth exemplary embodiment of the present disclosure of FIG. 15 has a pattern of an anode electrode 521 different from that in the above-described exemplary embodiments, but the other configurations are substantially the same so that a redundant description will be omitted.

FIG. 15 illustrates a part of a display panel in which four sub pixels SP_1, SP_2, SP_3, and SP_4 are disposed as an example and exemplarily illustrates a bank 516 including second open areas OA2_1 and OA2_2, anode electrodes 521a and 521b, and a third planarization layer 515c.

In FIG. 15, for the convenience of description, only a part of a configuration of a first type sub pixel SP_1 and a second type sub pixel SP_2 will be described by referring to reference numerals.

Referring to FIG. 15, the display panel according to the fifth exemplary embodiment of the present disclosure may include a pixel area in which a plurality of sub pixels SP_1, SP_2. SP_3, and SP_4 is provided and a wiring area in which various signal lines are disposed.

For example, in the pixel area, a plurality of first type sub pixels SP_1, second type sub pixels SP_2, third type sub pixels SP_3, and fourth type sub pixels SP_4 may be disposed.

The plurality of first type sub pixels SP_1, second type sub pixels SP_2, third type sub pixels SP_3, and fourth type sub pixels SP_4 may have different shapes, but may have substantially the same configuration.

For example, the first type sub pixels SP_1 may be a red, green, or blue sub pixel.

For example, the second type sub pixels SP_2 may be a red, green, or blue sub pixel.

For example, the third type sub pixels SP_3 may be a red, green, or blue sub pixel.

For example, the fourth type sub pixels SP_4 may be a red, green, or blue sub pixel.

For example, the first type sub pixels SP_1 and the third type sub pixels SP_3 may have an approximately circular shape, but the present disclosure is not limited thereto.

For example, the second type sub pixels SP_2 and the fourth type sub pixels SP_4 may have an approximately oval shape or rectangular shape, but the present disclosure is not limited thereto.

Here, shapes of the sub pixels SP_1, SP_2, SP_3, and SP_4 are defined with shapes of the anode electrodes 521a and 521b, but the present disclosure is not limited thereto.

In the meantime, according to the present disclosure, the anode electrodes 521a and 521b have the side mirror SM structure so that a reflective emission area is added as well as a main emission area so that each emission area may be expanded as compared with each of the sub pixels SP_1, SP_2, SP_3, and SP_4.

In the fifth exemplary embodiment of the present disclosure, the first type sub pixel SP_1 may include a first anode electrode 521a and the second type sub pixel SP_2 may include a second anode electrode 521b.

For example, the third planarization layer 515c may include first open areas OA1_1 and OA1_2 obtained by removing (opening) a part corresponding to a main emission area, a reflective emission area, and a non-emission area of the sub pixel. The first open areas OA1_1 and OA1_2 may include a first type of first open area OA1_1 of the first type sub pixel SP_1 and a second type of first open area OA1_2 of the second type sub pixel SP_2.

As seen from the plane, the first type of first open area OA1_1 may have an approximately circular shape with a bumpy edge such as an iris or wavy pattern, but is not limited thereto. For example, the edge of the first type of first open area OA1_1 may have a bumpy shape formed of a plurality of polygonal patterns.

As seen from the plane, the second type of first open area OA1_2 may have an approximately oval shape or rectangular shape with a bumpy edge such as an iris or wavy pattern, but is not limited thereto. For example, the edge of the second type of first open area OA1_2 may have a bumpy shape configured by a plurality of polygonal patterns.

Further, for example, in the first type sub pixel SP_1, one side portion of the third planarization layer 515c which is opposite to the first type of first open area OA1_1 may have a bumpy shape such as an iris or wavy pattern, like the edge of the first type of first open area OA1_1, as seen from the plane, but the present disclosure is not limited thereto. One side portion of the third planarization layer 515c may have a bumpy shape configured by a plurality of polygonal patterns.

Further, for example, in the second type sub pixel SP_2, the other side portion of the third planarization layer 515c which is opposite to the second type of first open area OA1_2 may have a bumpy shape such as an iris or wavy pattern, like the edge of the second type of first open area OA1_2, but the present disclosure is not limited thereto. The other one side portion of the third planarization layer 515c may have a bumpy shape configured by a plurality of polygonal patterns.

According to the fifth exemplary embodiment of the present disclosure, one side portion of the third planarization layer 515c has a bumpy shape, such as iris or wavy pattern. Therefore, the second area of the first anode electrode 521a deposited thereon may also have a bumpy shape, such as iris or wavy pattern as seen from the plane. However, the present disclosure is not limited thereto and the second area of the first anode electrode 521a of the present disclosure may have a bumpy shape formed of a plurality of polygonal patterns.

According to the fifth exemplary embodiment of the present disclosure, the other side portion of the third planarization layer 515c has a bumpy shape, such as iris or wavy pattern. Therefore, the second area of the second anode electrode 521b deposited thereon may also have a bumpy shape, such as iris or wavy pattern as seen from the plane. However, the present disclosure is not limited thereto and the second area of the second anode electrode 521b of the present disclosure may have a bumpy shape formed of a plurality of polygonal patterns.

As described above, an edge of the first open area OA1_1 of the first type sub pixel SP_1 has a bumpy shape having a concave area and a convex area, such as an iris or wavy pattern.

A shape of the end of the first anode electrode 521a may be a bumpy shape, corresponding to the shape of the first open area OA1. Referring to FIG. 15, the end of the first anode electrode 521a has a concave area CCA1 corresponding to a convex area CVA1 of the first open area OA1 and the end of the first anode electrode 521a has a convex area CVA2 corresponding to a concave area CCA2 of the first open area OA1.

That is, a distance DI between the concave area CCA1 of the end of the first anode electrode 521a of the first type sub pixel SP_1 and the first open area OA1_1 of the first type sub pixel SP_1 may be shorter than a distance D2 between the convex area CVA2 of the end of the first anode electrode 521a of the first type sub pixel SP_1 and the first open area OA1_1 of the first type sub pixel SP_1.

Accordingly, according to the fifth exemplary embodiment of the present disclosure, the edge of the first open area OA1_1 of the first type sub pixel SP_1 has a bumpy shape and the end of the first anode electrode 521a has a bumpy shape so that the periodicity of the pattern is reduced. By doing this, a concentric rainbow mura may be improved by the irregular reflection.

In the meantime, as described above, an edge of the first open area OA1_2 of the second type sub pixel SP_2 has a bumpy shape having a concave area and a convex area, such as an iris or wavy pattern.

The end of the second anode electrode 521b may be a shape corresponding to the bumpy shape of the first open area OA1_2.

The second open area OA2_2 of the second type sub pixel SP_2 may be smaller than the second open area OA2_1 of the first type sub pixel SP_1. At this time, the second type sub pixel SP_2 may be a green sub pixel.

That is, the second type sub pixel SP_2 which is a green sub pixel may be disposed to have a smallest size and the least effects on the rainbow mura so that an end of the second anode 521b may have a shape corresponding to the bumpy shape of the first open area OA1_2. Therefore, a width of the end of the second anode electrode 521b of the second type sub pixel SP_2 may be designed to be reduced or minimized.

The end of the second anode electrode 521b may be formed to have a minimum width in consideration of the process margin.

The exemplary embodiments of the present disclosure can also be described as follows:

According to an aspect of the present disclosure, a display device includes a substrate including a plurality of sub pixels; a transistor disposed above the substrate; a planarization layer which is disposed above the transistor and has a first open area; an anode electrode which is disposed in the first open area and a side portion of the planarization layer opposite to the first open area; a bank which covers a part of the anode electrode and has a second open area corresponding to the first open area; an organic layer which is disposed on the anode electrode exposed by the second open area; and a cathode electrode disposed on the organic layer, and a side portion of the planarization layer has a bumpy shape as seen from the plane and an end of the anode electrode has a bumpy shape as seen from the plane.

The anode electrode may have a side portion corresponding to the side portion of the planarization layer, the anode electrode, the organic layer, and the cathode electrode may configure a light emitting diode, the light emitting diode may form a main emission area, a side portion of the anode electrode may form a reflective emission area, the reflective emission area may be formed in a vicinity of the main emission area, and a non-emission area may be formed between the main emission area and the reflective emission area.

The anode electrode may have a portion extending from the side portion of the planarization layer to a top surface.

The second open area of the plurality of sub pixels may have a circular, oval, or rectangular shape.

The first open area of the plurality of sub pixels may have a bumpy edge formed of an iris or wavy pattern, or a plurality of polygonal patterns and an end of the anode electrode may have a shape corresponding to the bumpy shape of the first open area of the plurality of sub pixels.

A width of a portion of the anode electrode extending from the side portion of the planarization layer to the top surface may be constant.

The plurality of sub pixels may include a first sub pixel and a second sub pixel, the second open area of the first sub pixel may be a circular shape and the second open area of the second sub pixel may have an oval shape or a rectangular shape.

The first open area of the first sub pixel and the first open area of the second sub pixel may have a bumpy edge formed of an iris or wavy pattern or a plurality of polygonal patterns.

An end of the anode electrode of the first sub pixel may have a concave area corresponding to a convex area of the first open area of the first sub pixel and a convex area corresponding to a concave area of the first open area of the first sub pixel.

An end of the anode electrode of the second sub pixel may have a shape corresponding to the bumpy shape of the first open area of the second sub pixel.

A distance between the concave area of the end of the anode electrode of the first sub pixel and the first open area of the first sub pixel may be shorter than a distance between the convex area of the end of the anode electrode of the first sub pixel and the first open area of the first sub pixel.

The first sub pixel may be a red sub pixel or a blue sub pixel and the second sub pixel may be a green sub pixel.

The second open area of the second sub pixel may be smaller than the second open area of the first sub pixel.

The side portion of the anode electrode may be the end of the anode electrode.

The first open area may have a bumpy edge formed of an iris or wavy pattern, or a plurality of polygonal patterns and the end of the anode electrode may have the same shape as the bumpy shape of the first open area.

A boundary of a top surface of the planarization layer may coincide with the end of the anode electrode.

The planarization layer may have a contact hole which electrically connects the transistor and the anode and a part of the end of the anode electrode disposed in the contact hole may coincide with an end of the contact hole.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. The protective scope of the present disclosure should be construed based on the following claims, and all the technical concepts in the equivalent scope thereof should be construed as falling within the scope of the present disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure. CLAIMS

1. A display device, comprising:
a substrate including a plurality of sub pixels;
a transistor disposed above the substrate;
a planarization layer which is disposed above the transistor and has a first open area;
an anode electrode which is disposed in the first open area and a periphery surface of the planarization layer adjacent to the first open area;
a bank which covers a part of the anode electrode and has a second open area overlapping the first open area from a plan view;
an organic layer disposed on the anode electrode; and
a cathode electrode disposed on the organic layer,
wherein the periphery surface of the planarization layer has protrusions from a plan view and an end of the anode electrode has protrusions from a plan view.

2. The display device according to claim 1, wherein the anode electrode has a periphery surface corresponding to the periphery surface of the planarization layer, the anode electrode, the organic layer, and the cathode electrode configure a light emitting diode, the light emitting diode forms a main emission area, a periphery surface of the anode electrode forms a reflective emission area, the reflective emission area is formed in a vicinity of the main emission area, and a non-emission area is formed between the main emission area and the reflective emission area.

3. The display device according to claim 2, wherein the anode electrode has a portion extending from the periphery surface of the planarization layer to a top surface of the planarization layer.

4. The display device according to claim 3, wherein the second open area of the plurality of sub pixels has a circular, oval, or rectangular shape from a plan view.

5. A display device, comprising:
a substrate including a plurality of sub pixels;
a transistor disposed above the substrate;
a planarization layer which is disposed above the transistor and has a first open area;
an anode electrode which is disposed in the first open area and a side portion of the planarization layer adjacent to the first open area;
a bank which covers a part of the anode electrode and has a second open area overlapping the first open area from a plan view;
an organic layer disposed on the anode electrode; and
a cathode electrode disposed on the organic layer,
wherein the side portion of the planarization layer has a bumpy shape from a plan view and an end of the anode electrode has a bumpy shape from a plan view.

6. The display device according to claim 5, wherein the anode electrode has a side portion corresponding to the side portion of the planarization layer, the anode electrode, the organic layer, and the cathode electrode configure a light emitting diode, the light emitting diode forms a main emission area, a side portion of the anode electrode forms a reflective emission area, the reflective emission area is formed in a vicinity of the main emission area, and a non-emission area is formed between the main emission area and the reflective emission area.

7. The display device according to claim 6, wherein the anode electrode has a portion extending from the side portion of the planarization layer to a top surface of the planarization layer.

8. The display device according to claim 7, wherein the second open area of the plurality of sub pixels has a circular, oval, or rectangular shape from a plan view.

9. The display device according to claim 8, wherein the first open area of the plurality of sub pixels has a bumpy edge formed of an iris or wavy pattern, or a plurality of polygonal patterns and an end of the anode electrode has a shape corresponding to the bumpy shape of the first open area of the plurality of sub pixels.

10. The display device according to claim 9, wherein a width of a portion of the anode electrode extending from the side portion of the planarization layer to the top surface is constant.

11. The display device according to claim 7, wherein the plurality of sub pixels includes a first sub pixel and a second sub pixel, the second open area of the first sub pixel is a circular shape and the second open area of the second sub pixel has an oval shape or a rectangular shape.

12. The display device according to claim 11, wherein the first open area of the first sub pixel and the first open area of the second sub pixel have a bumpy edge formed of an iris or wavy pattern or a plurality of polygonal patterns,
wherein an end of the anode electrode of the first sub pixel has a concave area corresponding to a convex area of the first open area of the first sub pixel and a convex area corresponding to a concave area of the first open area of the first sub pixel, and
wherein an end of the anode electrode of the second sub pixel has a shape corresponding to the bumpy shape of the first open area of the second sub pixel.

13. The display device according to claim 12, wherein a distance between the concave area of the end of the anode electrode of the first sub pixel and the first open area of the first sub pixel is shorter than a distance between the convex area of the end of the anode electrode of the first sub pixel and the first open area of the first sub pixel.

14. The display device according to claim 12, wherein the first sub pixel is a red sub pixel or a blue sub pixel and the second sub pixel is a green sub pixel.

15. The display device according to claim 12, wherein the second open area of the second sub pixel is smaller than the second open area of the first sub pixel.

16. The display device according to claim 6, wherein the side portion of the anode electrode is the end of the anode electrode.

17. The display device according to claim 16, wherein the first open area has a bumpy edge formed of an iris or wavy pattern, or a plurality of polygonal patterns and the end of the anode electrode has the same shape as the bumpy shape of the first open area.

18. The display device according to claim 17, wherein a boundary of a top surface of the planarization layer coincides with the end of the anode electrode.

19. The display device according to claim 5, wherein the planarization layer has a contact hole which electrically connects the transistor and the anode, and
wherein a part of the end of the anode electrode disposed in the contact hole coincides with an end of the contact hole.

20. A display device, comprising:
a substrate;
a light emitting diode on the substrate, the light emitting diode including an anode electrode, a cathode electrode, and an organic layer between the anode electrode and the cathode electrode;
a transistor electrically connected to the light emitting diode, the transistor between the substrate and the light emitting diode;
a planarization layer on the transistor;
a first open area within the planarization layer, the light emitting diode disposed in the first open area; and
a bank on the planarization layer and adjacent to the light emitting diode;
a second open area within the bank,
wherein the second open area and the first open area overlap with each other from a plan view.

21. The display device of claim 20, wherein the planarization layer includes a first side surface and a second side surface opposite the first side surface and a bottom surface between the first and second side surfaces,
wherein the anode electrode continuously and contiguously extends along the first side surface, the bottom surface, and the second side surface of the planarization layer, and
wherein the first open area is within an area defined by the bottom surface and the first and second side surfaces.

22. The display device of claim 21, wherein the organic layer is on the anode electrode, and
wherein the organic layer is spaced apart from the first side surface of the planarization layer and the second side surface of the planarization layer, and
wherein the cathode electrode is on the organic layer and the cathode electrode is spaced apart from the first side surface of the planarization layer and the second side surface of the planarization layer.

23. The display device of claim 22, wherein the bank includes a first upper surface, a first side wall extending from the first upper surface, a second upper surface, and a second side wall extending from the second upper surface, the second side wall opposite the first side wall,
wherein the cathode electrode continuously and contiguously extends along the first upper surface, the first side wall, the second side wall, and the second upper surface of the bank, and
wherein the second open area is within an area defined by the first side wall and the second side wall.

24. The display device of claim 23, wherein the anode electrode at the first side surface of the planarization layer is spaced apart from the cathode electrode at the first side wall of the bank.

25. The display device of claim 21, wherein the first side surface of the planarization layer and the second side surface of the planarization layer have protrusions seen from a plan view.

26. The display device of claim 21, wherein the anode electrode at the first side surface of the planarization layer and the anode electrode at the second side surface of the planarization layer have protrusions seen from a plan view.

27. The display device according to claim 20, wherein the second open area overlaps with a main emission area from a plan view,
wherein the anode electrode at the first side surface of the planarization layer and the anode electrode at the second side surface of the planarization layer overlaps with a reflective emission area from a plan view, and wherein a non-emission area is between the main emission area and the reflective emission area from a plan view.

28. The display device according to claim 20, wherein the second open area has a circular, oval, or rectangular shape from a plan view.

29. The display device according to claim 20, wherein the planarization layer has a contact hole which electrically connects the transistor and the anode electrode of the light emitting diode via a connection electrode,
wherein the anode electrode extends over the first side surface of the planarization layer and is disposed along the contact hole,
wherein the anode electrode is electrically connected with the connection electrode.

30. The display device according to claim 26, wherein the protrusions include ridges and valleys.
